(19) United States
(12) Patent Application Publication
(10) Pub. No.: US 2025/0353784 A1
(43) Pub. Date: Nov. 20, 2025

(54) METHOD FOR PRODUCING RESIN LAYER-ATTACHED GLASS PLATE, RESIN LAYER-ATTACHED GLASS PLATE, GLASS PLATE, SOLAR CELL MODULE, AND METHOD FOR PRODUCING SOLAR CELL MODULE

(71) Applicant: AGC Inc., Tokyo (JP)

(72) Inventors: Masao OZEKI, Tokyo (JP); Yusuke MORISHIMA, Tokyo (JP); Yusuke KOBAYASHI, Tokyo (JP); Takumi NAGASAKO, Tokyo (JP); Yusuke FUJIWARA, Tokyo (JP)

(73) Assignee: AGC Inc., Tokyo (JP)

(21) Appl. No.: 19/071,227

(22) Filed: Mar. 5, 2025

Related U.S. Application Data
(63) Continuation of application No. PCT/JP2025/003808, filed on Feb. 5, 2025.

(30) Foreign Application Priority Data
May 15, 2024 (JP) 2024-079514

(51) Int. Cl. C03C 17/32; C03C 15/00; C03C 21/00; H10F 19/80

(52) U.S. Cl. CPC C03C 17/32; C03C 15/00; C03C 21/002; H10F 19/804; C03C 2218/31

(57) ABSTRACT

A method for producing a resin layer-attached glass plate by which the resin layer-attached glass plate is obtained with excellent resistance to falling objects. The method for producing a resin layer-attached glass plate includes performing etching and cleaning on at least one surface of a glass plate, and then, forming a resin layer on the one surface without substantially increasing scratches on the one surface.

This application is a continuation of PCT Application No. PCT/JP2025/003808, filed on Feb. 5, 2025, which is based upon and claims the benefit of priority from Japanese Patent Application No. 2024-079514 filed on May 15, 2024. The contents of those applications are incorporated herein by reference in their entireties.

### TECHNICAL FIELD

The present invention relates to a method for producing a resin layer-attached glass plate.

The present invention also relates to a resin layer-attached glass plate and a glass plate.

The present invention further relates to a solar cell module and a method for producing a solar cell module.

### BACKGROUND ART

In recent years, cover glasses have been used for the purpose of protection and appearance improvement of display devices of mobile phones, smart phones, tablet terminals and the like. The cover glasses for these applications are required to have high strength in order to prevent breakage by impact or the like.

Further, such cover glasses may also be used for protection of solar cell modules, various sensors and the like.

On the other hand, an etching method is known as a technique for thickness reduction of glass plates. For example, Patent Document 1 discloses a method of etching a surface of a glass plate with an etching solution containing hydrofluoric acid.

### PRIOR ART DOCUMENTS

### Patent Documents

Patent Document 1: JP-A-2017-081767

### DISCLOSURE OF INVENTION

### Technical Problem

The present inventors have studied the etching of glass plates as described in Patent Document 1 to obtain resin layer-attached glass plates, and have found that there is room for improvement in the resistance of the obtainable resin layer-attached glass plates to falling objects such as hail.

In view of the above-mentioned problem, it is an object of the present invention to provide a method for producing a resin layer-attached glass plate by which the resin layer-attached glass plate is obtained with excellent resistance to falling objects.

It is also an object of the present invention to provide a resin layer-attached glass plate.

Further, it is an object of the present invention to provide a glass plate.

Furthermore, it is an object of the present invention to provide a solar cell module and a method for producing a solar cell module.

### Solution to Problem

As a result of intensive studies on the above-mentioned problem, the present inventors have found that a resin layer-attached glass plate is obtained with excellent resistance to falling objects by, after etching a surface of a glass plate, forming a resin layer on the surface of the glass plate without substantially increasing scratches on the surface, and thus have accomplished the present invention.

In other words, the present inventors have found the following solutions to the above-mentioned problem.
[1] A method for producing a resin layer-attached glass plate, comprising performing etching and cleaning on at least one surface of a glass plate, and then, forming a resin layer on the one surface without substantially increasing scratches on the one surface.
[2] The method for producing a resin layer-attached glass plate according to [1], wherein the resin layer is formed on the one surface without allowing contact of any object other than the resin layer.
[3] The method for producing a resin layer-attached glass plate according to [1] or [2], wherein the glass plate is of chemically strengthened glass or physically strengthened glass.
[4] The method for producing a resin layer-attached glass plate according to [1] or [2], wherein the etching is performed only on the one surface of the glass plate.
[5] A resin layer-attached glass plate, comprising a glass plate and a resin layer,
wherein the increase amount of the number density of concave portions in at least one surface of the glass plate by an etching test of the glass plate is 10 number/cm² or less,
provided that the etching test is a test of immersing the glass plate in an etching solution containing 5 mass % hydrogen fluoride, 15 mass % hydrogen chloride and 80 mass % water for 10 minutes under a condition that the temperature of the etching solution is set at 25° C.
[6] The resin layer-attached glass plate according to [5], wherein the glass plate is of chemically strengthened glass or physically strengthened glass.
[7] The resin layer-attached glass plate according to [6], wherein the glass plate satisfies at least one of the following requirements 1 and 2:
requirement 1: the depth of layer of compressive stress on one surface side of the glass plate is smaller than the depth of layer of compressive stress on the other surface side of the glass plate; and
requirement 2: the compressive stress on the one side of the glass plate is lower than the compressive stress on the other side of the glass plate.
[8] A glass plate comprising concave portions with a size of 1 to 100 μm and a depth of 0.01 to 10 μm at 0.1 number/cm² or more in at least one surface of the glass plate.
[9] The glass plate according to [8], wherein the increase amount of the number density of the concave portions in the at least one surface by an etching test of the glass plate is 10 number/cm² or less,
provided that the etching test is a test of immersing the glass plate in an etching solution containing 5 mass % hydrogen fluoride, 15 mass % hydrogen chloride and 80 mass % water for 10 minutes under a condition that the temperature of the etching solution is set at 25° C.
[10] The glass plate according to [8], wherein the glass plate is of chemically strengthened glass or physically strengthened glass.
[11] The glass plate according to [10], wherein the glass plate satisfies at least one of the following requirements 1 and 2:
requirement 1: the depth of layer of compressive stress on one surface side of the glass plate is smaller than the depth of layer of compressive stress on the other surface side of the glass plate; and
requirement 2: the compressive stress on the one side of the glass plate is lower than the compressive stress on the other side of the glass plate.
[12] The glass plate according to any one of [8] to [11], wherein the glass plate comprises, in mol % on the oxide basis,
52 to 75% of SiO₂,
0 to 20% of Al₂O₃, and
1 to 20% of Na₂O.
[13] A solar cell module, comprising: the glass plate according to any one of [8] to [12]; and a solar cell substrate,
wherein the surface of the glass plate in which the increase amount of the number density of the concave portions by the etching test of the glass plate is 10 number/cm² or less is arranged on a solar cell substrate side.
[14] A solar cell module, comprising a glass plate and a solar cell substrate, wherein the glass plate is of physically strengthened glass, and wherein the glass plate comprises concave portions with a size of 1 to 100 μm and a depth of 0.01 to 10 μm at 0.1 number/cm² or more in a solar cell substrate-side surface of the glass plate.
[15] A solar cell module, comprising: a solar cell substrate having a light receiving surface and a back surface opposite to the light receiving surface; and a light receiving surface-side glass plate arranged on a light receiving surface side of the solar cell substrate,
wherein the light receiving surface-side glass plate satisfies at least one of the following requirements A1, A2 and A3:
requirement A1: the depth of layer of compressive stress on a solar cell substrate side of the light receiving surface-side glass plate is smaller than the depth of layer of compressive stress on a side of the light receiving surface-side glass plate opposite to the solar cell substrate side;
requirement A2: the compressive stress on the solar cell substrate side of the light receiving surface-side glass plate is lower than the compressive stress on the side of the light receiving surface-side glass plate opposite to the solar cell substrate side; and
requirement A3: the light receiving surface-side glass plate is warped in a convex shape toward the side opposite to the solar cell substrate side.
[16] The solar cell module according to [15], wherein at least a part of a peripheral edge region of the light receiving surface-side glass plate is reduced in thickness to define a step portion on a surface of the light receiving surface-side glass plate opposite to the solar cell substrate.
[17] A method for producing a solar cell module, comprising: performing etching and cleaning on at least one surface of a glass plate; and placing a solar cell substrate on the one surface side.
[18] A method for producing a solar cell module, comprising: providing a solar cell substrate with a light receiving surface and a back surface opposite to the light receiving surface; arranging a light receiving surface-side glass plate on the light receiving surface side; and arranging a back surface-side glass plate on the back surface side,
wherein the method comprises performing etching and cleaning on at least one of a solar cell substrate-side surface of the light receiving surface-side glass plate and a surface of the back surface-side glass plate opposite to the solar cell substrate.
[19] The method for producing a solar cell module according to [18], wherein the etching and cleaning are performed on the back surface-side glass plate with a hole formed therein.

### Advantageous Effects of Invention

According to the present invention, there is provided a method for producing a resin layer-attached glass plate by which the resin layer-attached glass plate is obtained with excellent resistance to falling objects.

According to the present invention, there is also provided a resin layer-attached glass plate.

According to the present invention, there is further provided a glass plate.

According to the present invention, there are furthermore provided a solar cell module and a method for producing a solar cell module.

### BRIEF DESCRIPTION OF DRAWINGS

FIG. 1 is a schematic cross-sectional view illustrating an embodiment of the resin layer-attached glass plate.

FIG. 2 is a schematic cross-sectional view illustrating an embodiment of the solar cell module of the present invention.

FIG. 3 is a schematic cross-sectional view illustrating another embodiment of the solar cell module of the present invention.

FIG. 4 is a schematic cross-sectional view illustrating a modified example of the another of the solar cell module of the present invention.

FIG. 5 is a cross-sectional view illustrating an example of the solar cell module in which the requirement A3 is satisfied.

FIG. 6 is a top view illustrating a glass plate used in an embodiment of the solar cell module of the present invention.

FIG. 7 is a cross-sectional view of the glass plate as taken along line A-A of FIG. 6.

FIG. 8 is a schematic cross-sectional view illustrating an embodiment of the solar cell module in which a glass plate with a step portion is used as a light receiving surface-side glass plate.

FIG. 9 is a schematic cross-sectional view illustrating a modified example the embodiment of the solar cell module in which the glass plate with a step portion is used as the light receiving surface-side glass plate.

FIG. 10 is a schematic cross-sectional view illustrating an embodiment of the solar cell module in which a glass plate with a step portion is used as a back surface-side glass plate.

FIG. 11 is a top view illustrating a back surface-side glass plate with holes.

FIG. 12 is a schematic view illustrating a falling ball impact strength tester used for evaluation of strength against falling objects.

FIG. 13 is a picture of an example of a sample having cracks caused during testing with a falling ball impact strength tester.

FIG. 14 is a schematic view illustrating a microscopic observation image of concave portions after etching.

### DESCRIPTION OF EMBODIMENTS

Hereinafter, the present invention will be described in detail below. It is however noted that the present invention is not limited to the following embodiments and can be embodied by making various changes and modifications within the range that does not depart from the gist of the present invention.

In the present specification, the glass composition is expressed in mole percentages on the oxide basis, and mol % is sometimes simply indicated as %. Further, a numerical range expressed using “to” means a range including numerical values described before and after “to” as lower and upper limits.

In the present specification, “chemically strengthened glass” refers to glass having been subjected to chemical strengthening treatment, and “glass for chemical strengthening” refers to glass before being subjected to chemical strengthening treatment.

In the present specification, “physically strengthened glass” refers to glass having been subjected to physical strengthening treatment.

In the present specification, a surface of a glass plate refers to either one of two main largest-area surfaces of the glass plate.

In a glass composition, “containing substantially no” means that it is not contained except as an unavoidable impurity in the raw material etc., that is, it is not intentionally contained. More specifically, the content of a component other than those described as the glass composition is, for example, preferably less than 0.1 mol %, more preferably 0.08 mol % or less, still more preferably 0.05 mol % or less.

In the present specification, a “stress profile” refers to a pattern representing a compressive stress value with the depth from the glass surface taken as a variable. A negative compressive stress value means tensile stress.

In the present specification, the measurement of a “stress profile” can be done by a method using an optical waveguide surface stress meter and a scattered light photoelastic stress meter in combination.

An optical waveguide surface stress meter is capable of accurately measuring stress on glass in a short time. As an example of the optical waveguide surface stress meter, FSM-6000 manufactured by Orihara Industrial Co., Ltd. may be mentioned. In principle, however, the optical waveguide surface stress meter can only measure stress when the refractive index decreases from the sample surface toward the inside. In chemically strengthened glass, a layer formed by exchanging sodium ions inside the glass with potassium ions outside the glass decreases in refractive index from the sample surface to the inside, and thus stress on such a layer can be measured with the optical waveguide surface stress meter. However, the stress on a layer formed by exchanging lithium ions inside the glass with sodium ions outside the glass cannot be accurately measured with the optical waveguide surface stress meter.

By a method using a scattered light photoelastic stress meter, stress can be measured irrespective of the refractive index distribution. As an example of the scattered light photoelastic stress meter, SLP2000 by Orihara Industrial Co., Ltd. may be mentioned. However, the scattered light photoelastic stress meter is susceptible to the influence of surface scattering and may not be capable of accurately measuring stress near the surface.

For the above reasons, accurate stress measurement is enabled by the combined use of two types of measurement devices, i.e., the optical waveguide surface stress meter and the scattered light photoelastic stress meter.

In the present specification, a depth of layer of compressive stress means a depth at which the compressive stress value becomes zero.

### <Method for Producing Resin Layer-Attached Glass Plate>

The method for producing a resin layer-attached glass plate according to the present invention includes performing etching and cleaning on at least one surface of a glass plate, and then, forming a resin layer on the one surface without substantially increasing scratches on the one surface.

The mechanism by which a resin layer-attached glass plate with excellent resistance to falling objects is obtained by the resin layer-attached glass plate producing method of the present invention is not always certain, but is assumed as follows by the present inventors.

In the resin layer-attached glass plate producing method of the present invention, etching and cleaning are performed. It is considered that the shape of scratches on the glass plate is changed by etching whereby breakage starting from the scratches becomes less likely to occur. In the resin layer-attached glass plate producing method of the present invention, the resin layer is then formed, without substantially increasing scratches, on the etched and cleaned surface. It is considered that: the shape of the scratches changed by etching is maintained; and the state in which breakage is less likely to occur is maintained without new scratches being caused during the formation of the resin layer and in the subsequent step.

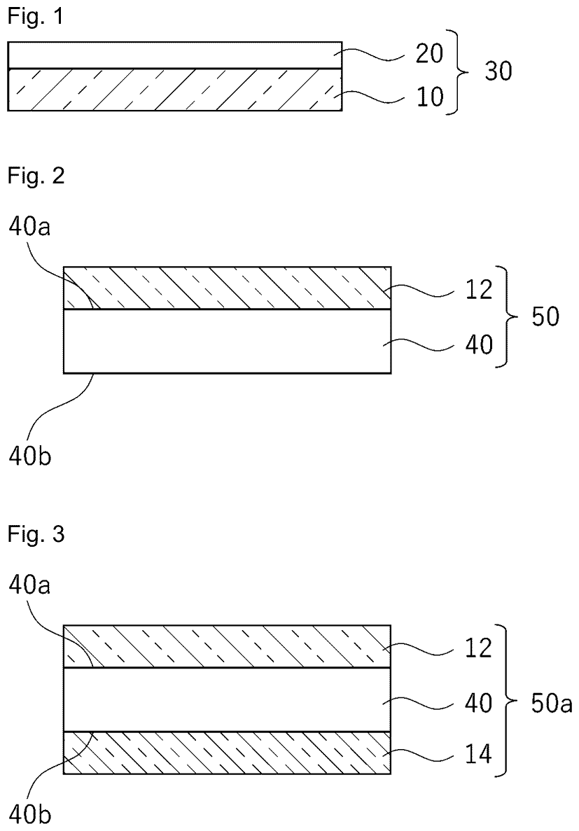

As a consequence, the resin layer-attached glass plate (see FIG. 1) with excellent resistance to falling objects is obtained by the resin layer-attached glass plate producing method of the present invention.

Hereinafter, a step of performing etching and cleaning on at least one surface of a glass plate is also referred to as an “etching step”; and a step of forming a resin layer on the one surface is also referred to as a “resin layer forming step”.

Further, in the present specification, scratches on a glass plate include visible scratches and non-visible scratches (also called “latent scratches”).

The resin layer-attached glass plate producing method of the present invention will be now described below.

### [Etching Step]

In the resin layer-attached glass plate producing method of the present invention, the etching step is conducted in which etching and cleaning are performed on at least one surface of the glass plate.

The glass plate to be subjected to the etching step is not particularly limited. Various glass plates are usable. For example, the type of the glass plate is not particularly limited. The glass plate can be of figured glass or float glass. The glass plate can be of glass obtained by a fusion process or flat glass obtained by a roll-out process.

Further, the glass plate can be of strengthened glass. In other words, the glass plate can be of chemically strengthened glass or physically strengthened glass. Examples of the glass plate include a glass plate obtained by performing physical strengthening treatment on figured glass, a glass plate obtained by performing chemical strengthening treatment on figured glass, a glass plate obtained by performing physical strengthening treatment on float glass and a glass plate obtained by performing chemical strengthening treatment on float glass.

Examples of the glass plate to be subjected to the etching step will be described in detail below.

The chemically strengthened glass can be, for example, glass obtained by performing chemical strengthening treatment on plate glass. For example, an ion exchange process may be used as a method of chemical strengthening treatment. The ion exchange process causes compressive stress on a surface of glass by immersing the glass in a processing liquid (e.g. a molten salt containing at least one of potassium nitrate and sodium nitrate) and exchanging ions of small ionic radii in the glass (such as Li ions and Na ions) with ions of larger ionic radii (such as Na ions and K ions). The compressive stress is caused in the whole surface of the glass, to form a layer of compressive stress with a uniform thickness in the whole surface of the glass.

The magnitude of compressive stress on the glass surface (hereinafter referred to as “surface compressive stress”) and the depth of layer of compressive stress on the glass surface can be each adjusted according to the glass composition, the concentration of the processing liquid, the chemical strengthening treatment time and the chemical strengthening treatment temperature. The surface compressive stress is, for example, 200 MPa or higher, preferably 400 MPa or higher, more preferably 500 MPa or higher. On the other hand, the surface compressive stress is, for example, 1,200 MPa or lower, preferably 900 MPa or lower, more preferably 800 MPa or lower.

The depth of layer of compressive stress is, for example, 2 μm or larger, preferably 3 μm or larger, more preferably 5 μm or larger. On the other hand, the depth of layer of compressive stress is, for example, 100 μm or smaller, preferably 60 μm or smaller, more preferably 40 μm or smaller.

The chemically strengthened glass is not particularly limited so far as it is ion-exchanged. Examples of the chemically strengthened glass include those obtained by performing chemical strengthening treatment on aluminosilicate glass, soda glass, soda-lime glass, lithium silicate glass and the like.

The physically strengthened glass can be, for example, glass obtained by performing thermal strengthening treatment on glass having a glass transition temperature of 500° C. or higher and an average expansion coefficient α₅₀₋₃₅₀ of 70×10⁻⁷/° C. at 50 to 350° C. Examples of the glass having the above characteristic properties include soda-lime glass.

The thermal strengthening treatment refers to a process of rapidly cooling uniformly heated plate glass from a temperature near the softening point and thereby causing compressive stress on a surface of the glass due to a temperature difference between the surface of the glass and the inside of the glass. A typical example of the thermal strengthening treatment is tempering in which plate glass is produced by a float process etc., followed by heating the cut plate glass to a temperature near the softening point or the deformation point and then rapidly cooling the plate glass with the blow of a cooling medium onto the glass surface. The compressive stress is caused in the whole surface of the glass to form a layer of compressive stress with a uniform thickness in the whole surface of the glass. As compared to the chemical strengthening treatment, the thermal strengthening treatment is suitable for strengthening of thick glass plates.

The float glass refers to glass formed by a float process.

As mentioned above, the float glass may be subjected to physical strengthening treatment or chemical strengthening treatment.

The figured glass refers to glass formed by pushing a roll mold against glass by a roll-out process. The pattern formed on the surface of the figured glass is not particularly limited and can be a known pattern.

As mentioned above, the figured glass may be subjected to physical strengthening treatment or chemical strengthening treatment.

With increase of compressive stress on physically strengthened glass and on chemically strengthened glass, scratches are less likely to occur on glass surfaces. Further, scratches are less likely to occur even in deeper areas as the depths of layer of compressive stress are increased.

The composition of the glass plate is not particularly limited. For example, the glass plate preferably has a composition containing, in mol % on the oxide basis,
52 to 75% of SiO₂,
0 to 20% of Al₂O₃, and
1 to 20% of Na₂O.

The more preferable composition of the glass plate will be described below.

An embodiment of the more preferable composition of the glass plate contains, in mol % on the oxide basis,
52 to 75% of SiO₂,
0 to 20% of Al₂O₃
0 to 18% of Li₂O,
1 to 20% of Na₂O,
0 to 5% of K₂O,
0 to 20% of MgO,
0 to 20% of CaO,
0 to 20% of SrO,
0 to 20% of BaO,
0 to 10% of ZnO
0 to 1% of TiO₂,
0 to 8% of ZrO₂, and
0 to 5% of Y₂O₃.

The above embodiment of the more preferable glass composition (first glass composition) will be described in detail below.

SiO₂ is a component for forming a network structure in glass, and is also a component for improving chemical resistance. The content of SiO₂ is preferably 52% or more, more preferably 56% or more, still more preferably 60% or more, particularly preferably 64% or more. On the other hand, with a view to achieving improved meltability, the content of SiO₂ is preferably 75% or less, more preferably 73% or less, still more preferably 71% or less, particularly preferably 69% or less.

Al₂O₃ is a component capable of increasing surface compressive stress caused by chemical strengthening treatment. When Al₂O₃ is contained, the content of Al₂O₃ is preferably 1% or more, more preferably 2% or more, still more preferably 4% or more, particularly preferably 6% or more. On the other hand, with a view to preventing the devitrification temperature of glass from becoming too high, the content of Al₂O₃ is preferably 20% or less, more preferably 18% or less, still more preferably, in order, 17% or less, and 16% or less, most preferably 15% or less.

Na₂O is a component for improving glass meltability and causing surface compressive stress by ion exchange. The content of Na₂O is preferably 1% or more, more preferably 2% or more, particularly preferably 4% or more. Since too much Na₂O leads to deterioration of chemical strengthening properties, the content of Na₂O is preferably 20% or less, more preferably 18% or less, particularly preferably 16% or less, most preferably 14% or less.

K₂O is a component for lowering glass melting temperature and causing surface compressive stress by ion exchange, as in the case of Na₂O. When K₂O is contained, the content of K₂O is preferably 0% or more, more preferably 0.1% or more, still more preferably 0.3% or more, yet still more preferably 0.4% or more, particularly preferably 0.5% or more. Since too much K₂O leads to deterioration of chemical strengthening properties or deterioration of chemical resistance, the content of K₂O is preferably 5% or less, more preferably 4.8% or less, still more preferably 4.5% or less, particularly preferably 4.2% or less, most preferably 4.0% or less.

The total content of Na₂O and K₂O (Na₂O+K₂O) is preferably 1% or more, more preferably 2% or more, with a view to improving raw glass meltability and causing surface compressive stress by ion exchange.

Li₂O is a component for causing surface compressive stress by ion exchange. When Li₂O is contained, the content of Li₂O is preferably 1% or more, more preferably 2% or more, still more preferably 4% or more, particularly preferably 5% or more. On the other hand, with a view to stabilizing glass, the content of Li₂O is preferably 18% or less, more preferably 17% or less, still more preferably 16% or less, most preferably 15% or less.

The ratio of the content of K₂O to the total content of Li₂O, Na₂O and K₂O (hereinafter referred to as R₂O) as expressed by K₂O/R₂O is preferably 0.2 or lower to achieve improved chemical strengthening properties and improved chemical resistance. The ratio K₂O/R₂O is more preferably 0.15 or lower, still more preferably 0.10 or lower. The R₂O content is preferably 10% or more, more preferably 12% or more, still more preferably 15% or more. Further, the R₂O content is preferably 20% or less, more preferably 18% or less.

MgO is a component for stabilizing glass and for improving mechanical strength and chemical resistance and, thus is preferably contained in the case where the Al₂O₃ content is relatively low. When MgO is contained, the content of MgO is preferably 1% or more, more preferably 2% or more, still more preferably 3% or more, particularly preferably 4% or more. On the other hand, too much MgO tends to result in lower glass viscosity and to cause devitrification or phase separation. The content of MgO is preferably 20% or less, more preferably 19% or less, still more preferably 18% or less, particularly preferably 17% or less.

Each of CaO, SrO, BaO and ZnO is a component for improving glass meltability, and may be contained.

CaO is a component for improving glass meltability, when processed into chemically strengthened glass, improving glass fracturability, and may be contained. When CaO is contained, the content of CaO is preferably 0.5% or more, more preferably 1% or more, still more preferably 2% or more, particularly preferably 3% or more, most preferably 5% or more. On the other hand, the content of CaO is preferably 20% or less because, when it exceeds 20%, ion exchangeability is significantly lowered. The content of CaO is more preferably 14% or less, still more preferably, as stepwisely described in order, 10% or less, 8% or less, 6% or less, 3% or less, and 1% or less.

SrO is a component for improving glass meltability and, when processed into chemically strengthened glass, improving glass fracturability, and may be contained. When SrO is contained, the content of SrO is preferably 0.5% or more, more preferably 1% or more, still more preferably 2% or more, particularly preferably 3% or more, most preferably 5% or more. On the other hand, the content of SrO is preferably 20% or less because, when it exceeds 20%, ion exchangeability is significantly lowered. The content of SrO is more preferably 14% or less, still more preferably, as stepwisely described in order, 10% or less, 8% or less, 6% or less, 3% or less, and 1% or less.

BaO is a component for improving glass meltability and, when processed into chemically strengthened glass, improving glass fracturability, and may be contained. When BaO is contained, the content of BaO is preferably 0.5% or more, more preferably 1% or more, still more preferably 2% or more, particularly preferably 3% or more, most preferably 5% or more. On the other hand, when the content of BaO exceeds 20%, glass is significantly lowered in ion exchangeability. The content of BaO is preferably 20% or less, more preferably, as stepwisely described in order, 15% or less, 10% or less, 6% or less, 3% or less, and 1% or less.

ZnO is a component for improving glass meltability, and may be contained. When ZnO is contained, the content of ZnO is preferably 0.25% or more, more preferably 0.5% or more. On the other hand, when the content of ZnO exceeds 10%, glass is significantly lowered in weather resistance. The content of ZnO is preferably 10% or less, more preferably, as stepwisely described in order, 8% or less, 6% or less, 3% or less, and 1% or less.

ZrO₂ is a component for improving mechanical strength and chemical resistance and significantly increasing CS, and thus is preferably contained. The content of ZrO₂ is preferably 0.5% or more, more preferably 0.7% or more, still more preferably 1.0% or more, particularly preferably 1.2% or more, most preferably 1.5% or more. On the other hand, in order to suppress devitrification during melting, the content of ZrO₂ is preferably 8% or less, more preferably 7.5% or less, still more preferably 7% or less, particularly preferably 6% or less. Too much ZrO₂ leads to decrease of viscosity with increase of devitrification temperature. In order to suppress deterioration of formability due to such decrease of viscosity, the content of ZrO₂ is preferably 5% or less, more preferably 4.5% or less, still more preferably 3.5% or less, in the case where the forming viscosity is low.

With a view to achieving high chemical resistance, the ZrO₂/R₂O ratio is preferably 0.02 or higher, more preferably 0.04 or higher, still more preferably 0.06 or higher, particularly preferably 0.08 or higher, most preferably 0.1 or higher. The ZrO₂/R₂O ratio is preferably 0.2 or lower, more preferably 0.18 or lower, still more preferably 0.16 or lower, particularly preferably 0.14 or lower.

TiO₂ is not essential, and when TiO₂ is contained, the content of TiO₂ is preferably 0.05% or more, more preferably 0.1% or more. On the other hand, in order to suppress devitrification during melting, the content of TiO₂ is preferably 1% or less, more preferably 0.5% or less, still more preferably 0.3% or less.

Y₂O₃ is a component that has the effect of, when processed into chemically strengthened glass, making fractured pieces of the glass less likely to scatter, and may be contained. The content of Y₂O₃ is preferably 0.3% or more, more preferably 0.5% or more, still more preferably 0.7% or more, particularly preferably 1.0% or more. On the other hand, in order to suppress devitrification during melting, the content of Y₂O₃ is preferably 5% or less, more preferably 4% or less.

The first glass composition may contain a component (additional component) other than the above-mentioned components. Examples of the additional component include SnO₂, B₂O₃, La₂O₃, Nb₂O₅, Ta₂O₅ and CeO₂.

SnO₂ is not essential, and when SnO₂ is contained, the content of SnO₂ is preferably 0.5% or more, more preferably 1% or more, still more preferably 1.5% or more, particularly preferably 2% or more. On the other hand, in order to suppress devitrification during melting, the content of SnO₂ is preferably 4% or less, more preferably 3.5% or less, still more preferably 3% or less, particularly preferably 2.5% or less.

B₂O₃ is a component for improving glass chipping resistance and improving glass meltability, and may be contained. When B₂O₃ is contained, the content of B₂O₃ is preferably 0.5% or more, more preferably 1% or more, still more preferably 2% or more, with a view to achieving improved meltability. On the other hand, the content of B₂O₃ is preferably 10% or less because too much B₂O₃ tends to cause striae formulation or phase separation during melting and thereby result in low quality of glass for chemical strengthening. The content of B₂O₃ is more preferably 8% or less, still more preferably 6% or less, particularly preferably 4% or less.

Each of La₂O₃, Nb₂O₅ and Ta₂O₅ is a component for, when processed into chemically strengthened glass, making fractured pieces of the glass less likely to scatter, and may be contained to achieve high refractive index. When La₂O₃, Nb₂O₅ and Ta₂O₅ are contained, their total content (La₂O₃+Nb₂O₅+Ta₂O₅) is preferably 0.5% or more, more preferably 1% or more, still more preferably 1.5% or more, particularly preferably 2% or more. In order to make glass less likely to cause devitrification during melting, the La₂O₃+Nb₂O₅+Ta₂O₅ content is preferably 4% or less, more preferably 3% or less, still more preferably 2% or less, particularly preferably 1% or less.

Further, CeO₂ may be contained. In some cases, CeO₂ can suppress coloring by oxidation of glass. When CeO₂ is contained, the content of CeO₂ is preferably 0.03% or more, more preferably 0.05% or more, still more preferably 0.07% or more. With a view to achieving high transparency, the content of CeO₂ is preferably 1.5% or less, more preferably 1.0% or less.

In the case where chemically strengthened glass is used in colored form, a coloring component may be contained within the range that does not impair achievement of the desired chemical strengthening properties. Examples of the coloring component include Co₃O₄, MnO₂, Fe₂O₃, NiO, CuO, Cr₂O₃, V₂O₅, Bi₂O₃, SeO₂, Er₂O₃ and Nd₂O₃.

The total content of the coloring components is preferably in the range of 1% or less. In the case where the visible light transmittance of the glass is to be set to a higher value, it is preferable that these coloring components are not substantially contained.

With a view to improving the weather resistance of glass to ultraviolet rays, HfO₂, Nb₂O₅ and Ti₂O₃ may be contained. When HfO₂, Nb₂O₅ and Ti₂O₃ are contained to improve the weather resistance of glass to ultraviolet rays, their total content is preferably 1% or less, more preferably 0.5% or less, still more preferably 0.1% or less, so as not to influence the other properties.

As a fining agent for glass during melting, SO₃, SnO₂, a chloride and a fluoride may be appropriately contained. The fining agent, when contained too much, causes an influence on the strengthening properties. Thus, the total content of the fining agents in mass % on the oxide basis is preferably 2% or less, more preferably 1% or less, still more preferably 0.5% or less. The lower limit is not particularly limited, but is typically preferably 0.05% or more in mass % on the oxide basis.

There is no effect seen when SO₃ is contained too less as the fining agent. When SO₃ is contained as the fining agent, the content of SO₃ in mass % on the oxide basis is preferably 0.01% or more, more preferably 0.05% or more, still more preferably 0.1% or more. When SO₃ is contained as the fining agent, the content of SO₃ in mass % on the oxide basis is preferably 1% or less, more preferably 0.8% or less, still more preferably 0.6% or less.

The chloride, when contained too much, causes an influence on the physical properties such as strengthening properties. When the chloride is contained as the fining agent, the content of the chloride in mass % on the oxide basis is preferably 1% or less, more preferably 0.8% or less, still more preferably 0.6% or less. There is no effect seen when the chloride is contained too less as the fining agent. The content of the chloride in mass % on the oxide basis is preferably 0.05% or more, more preferably 0.1% or more, still more preferably 0.2% or more.

When SnO₂ is contained as the fining agent, the content of SnO₂ in mass % on the oxide basis is preferably 1% or less, more preferably 0.5% or less, still more preferably 0.3% or less. There is no effect seen when SnO₂ is contained too less as the fining agent. The content of SnO₂ is, in mass % on the oxide basis, preferably 0.02% or more, more preferably 0.05% or more, still more preferably 0.1% or more.

It is preferable that P₂O₅ is not contained. When P₂O₅ is contained, the content of P₂O₅ is preferably 2.0% or less, more preferably 1.0% or less, most preferably none.

It is preferable that As₂O₃ and Sb₂O₃ are not contained. When Sb₂O₃ is contained, the content of Sb₂O₃ is preferably 0.3% or less, more preferably 0.1% or less, most preferably none.

Another embodiment of the more preferable composition of the glass plate, the glass plate preferably contains, in mol % on the oxide basis,
60 to 76% of SiO₂,
0 to 10% of Al₂O₃,
10 to 18% of Na₂O,
0 to 5% of K₂O,
2 to 12% of MgO, and
0 to 15% of CaO.

The another embodiment of the more preferable composition of the glass plate (second glass composition) will be described in detail below. In the following description, percentages are mole percentages on the oxide basis unless otherwise specified.

SiO₂ is known as a component for forming a network structure in glass microstructure, and is a major component of glass. The content of SiO₂ is more preferably 61% or more, still more preferably 62% or more. Further, the content of SiO₂ is more preferably 74% or less, still more preferably 72% or less, particularly preferably 70% or less.

Al₂O₃ is a component for improving weather resistance of glass and has the effect of improving ion exchangeability of glass in chemical strengthening treatment. The content of Al₂O₃ is more preferably 0.1% or more, still more preferably 0.2% or more, particularly preferably 0.5% or more, and may be 1.0% or more. Further, the content of Al₂O₃ is more preferably 9% or less.

Na₂O is a component for lowering high-temperature viscosity and devitrification temperature of glass and improving meltability and formability of the glass. It is also a component for causing compressive stress by ion exchange and has the effect of increasing the depth of layer of compressive stress DOL. The content of Na₂O is more preferably 11% or more, still more preferably 12% or more. Further, the content of Na₂O is more preferably 16% or less, still more preferably 15% or less.

K₂O is not essential, but may be contained for the purpose of any one of improvement of glass meltability, improvement of chemical durability and increase of ion exchange speed. When K₂O is contained, the content of K₂O is more preferably 4% or less. Further, when K₂O is contained, the content of K₂O is more preferably 0.1% or more, still more preferably 0.5% or more.

Here, K₂O may not be contained in the second glass composition.

MgO is a component for stabilizing glass. The content of MgO is more preferably 3% or more, still more preferably 4% or more. Further, the content of MgO is more preferably 11% or less.

CaO is not essential, but is a component for stabilizing glass. With a view to achieving improved water resistance and chemical resistance, the content of CaO is more preferably 5% or more, still more preferably 6% or more, particularly preferably 7% or more. Further, the content of CaO is more preferably 13% or less, still more preferably 11% or less.

Here, CaO may not be contained in the second glass composition.

The second glass composition may contain a component (additional component) other than the above-mentioned components. Examples of the additional component include a fining agent such as a sulfate, Fe₂O₃, TiO₂, ZrO₂, SnO₂ and Sb₂O₃. The total content of the additional components is preferably 1% or less.

The plate thickness of the glass plate to be subjected to the etching step is not particularly limited, and is often 0.1 mm or larger, preferably 0.5 mm or larger, more preferably 1.0 mm or larger. Further, the plate thickness of the glass plate is often 10 mm or smaller, preferably 4 mm or smaller, more preferably 3 mm or smaller.

In the etching step, etching treatment is performed on the glass plate. As an example of the method of etching treatment, contact of the glass plate with an etching solution may be mentioned.

As the etching solution, an aqueous solution containing a fluorinated compound capable of releasing fluoride ions (F⁻) or hexafluorosilicate ions (SiF₆²⁻) can be used. Specific examples of the fluorinated compound include hydrogen fluoride (HF), ammonium fluoride (NH₄F), hexafluorosilicic acid (H₂SiF₆), and ammonium hexafluorosilicate ((NH₄)₂SiF₆).

The etching solution may preferably contain any other acidic compound in addition to the above compound. The other acidic compound may be, for example, at least one compound selected from the group consisting of sulfuric acid (H₂SO₄), nitric acid (HNO₃), hydrogen chloride (HCl) and phosphoric acid (H₃PO₄).

The content of the fluorinated compound in the etching solution is preferably 0.01 to 15 mass %, more preferably 0.1 to 10 mass %, still more preferably 1 to 8 mass %, relative to the total mass of the etching solution. In the etching solution, the above-mentioned fluorinated compound may be one type alone or a combination of two or more types.

Further, the content of the other acidic compound in the etching solution is preferably 0.1 to 30 mass %, more preferably 1 to 25 mass %, still more preferably 5 to 20 mass %, relative to the total mass of the etching solution. In the etching solution, the above-mentioned other acidic compound may be one type alone or a combination of two or more types.

Here, the rest of the etching solution is usually water.

The method for contact of the glass plate with the etching solution is not particularly limited, and can be, for example, immersion of the glass plate in the etching solution, showering of the glass plate with the etching solution or spraying of the etching solution onto the glass plate.

In the case where the glass plate is immersed in the etching solution, it is also preferable to conduct the immersion with convection of the etching solution.

In the case where the etching treatment is performed by contact of the glass plate with the etching solution, the treatment temperature is preferably 0° C. or higher, more preferably 10° C. or higher, still more preferably 20° C. or higher, and may be 40° C. or higher. Further, the treatment temperature is often lower than 100° C., preferably 90° C. or lower, more preferably 70° C. or lower.

In the case where the etching treatment is performed by contact of the glass plate with the etching solution, the contact time of the glass plate and the etching solution can be adjusted as appropriate and is, for example, preferably 30 seconds or more, more preferably 1 minute or more, still more preferably 5 minutes or more. Further, the contact time is preferably 10 hours or less, more preferably 1 hour or less, still more preferably 30 minutes or less.

In the etching step, cleaning is performed after the etching. The method of cleaning is not particularly limited. For example, contact of the etched glass plate with a cleaning liquid may be mentioned.

The cleaning liquid is not particularly limited, but is preferably water. As the water, industrial water, tap water, distilled water, ion-exchanged water and pure water can be used. Preferred is distilled water, ion-exchanged water or pure water.

The method for contact of the etched glass plate with the cleaning liquid can be, for example, immersion of the glass plate in the cleaning liquid, showering of the glass plate with the cleaning liquid or spraying of the cleaning liquid onto the glass plate.

In the case where the glass plate is immersed in the cleaning liquid, it is also preferable to conduct the immersion with convection of the cleaning liquid.

The cleaning in the etching step may be performed repeatedly.

Further, in the etching step, the etching and cleaning may be performed repeatedly. For example, the etching and cleaning may be repeated twice or more. In the case where the etching and cleaning are repeated, the number of repetitions of the etching and cleaning may be, for example, five or less.

The glass plate to be subjected to the etching step may have a protection film on one surface thereof. Further, the glass plate to be subjected to the etching step may have an anti-reflection layer (AR layer) on one surface thereof.

In the case where the glass plate to be subjected to the etching step has a protection film, the protection film used is preferably made of a material which is not degraded by the etching solution in the etching step.

The etching step may be performed only on one surface of the glass plate, or may be performed on one surface and the other surface of the glass plate.

### [Resin Layer Forming Step]

In the resin layer-attached glass plate producing method of the present invention, the resin layer forming step is conducted after the etching step. In the resin layer-attached glass plate producing method of the present invention, the resin layer is formed without substantially increasing scratches on the one surface.

The resin layer forming step needs to be conducted on at least the surface of the glass plate on which the etching treatment has been performed in the etching step. The resin layer forming step may be conducted only on one of the surfaces of the glass plate or may be conducted on both of the surfaces of the glass plate.

The material for forming the resin layer is not particularly limited, and can be a known resin. Examples of the material for forming the resin layer include a polyolefin (such as polyethylene or polypropylene), a polyester (such as polyethylene terephthalate or polyethylene naphthalate), a polycarbonate, a polyurethane, a polyimide, and the like.

Furthermore, the resin layer may be a pressure sensitive adhesive layer or an adhesive layer.

Examples of the material of the pressure sensitive adhesive layer or adhesive layer include a polyacrylic resin, a polyolefin resin, a polyvinyl alcohol resin, an ethylene-vinyl acetate resin, a silicone resin, an epoxy resin, a rubber resin, and the like.

The resin layer may consist of one layer or may consist of two or more layers.

In the resin layer forming step, “without substantially increasing scratches” means no increase of visible scratches and substantially no increase of non-visible scratches (latent scratches). Here, substantially no increase of latent scratches means that, when the later-described etching test is conducted, the increase amount of the number density of concave portions in the surface of the glass plate on which the resin layer is to be formed is 10 number/cm² or less. The increase amount of the number density of the concave portions is preferably 5 number/cm² or less, more preferably 1 number/cm² or less. The increase amount of the number density of the concave portions may be 0 number/cm² or more.

A method for measuring the increase amount of the number density is as described later.

As an example of the method of the resin layer forming step of the present invention, there may be mentioned a method of forming the resin layer without allowing contact of any object other than the resin layer with the one surface. More specifically, for example, the resin layer may be laminated onto the surface of the glass plate on which the etching treatment has been performed. The resin layer may be formed by applying a composition containing the constituent component of the resin layer.

Here, “forming the resin layer without allowing contact of any object other than the resin layer with the one surface” means that no contact of any object other than the resin layer with the one surface is allowed between the etching step and the resin layer forming step. Contact of any object other than the resin layer with the one surface means contact of a solid object other than the resin layer with the one surface. Examples of such contact include a step of polishing the one surface, a step of transferring the glass plate by contact of a transfer roller or the like with the one surface, a step of storing the glass plate by contact of another object with the one surface, and the like.

The method of the resin layer forming step of the present invention is not limited to the method of forming the resin layer without allowing contact of any object other than the resin layer with the one surface.

For example, a method may be mentioned in which the glass plate is transferred by contact of a member made of a soft material such as a resin with the one surface, followed by forming the resin layer.

Further, a method may also be mentioned in which a member to be brought into contact with the one surface is provided with a highly smoothed surface for contact with the glass plate, followed by transferring the glass plate by contact with such a member and then forming the resin layer.

In addition to the above, a method may be mentioned in which the glass plate is transferred by contact with only side faces of the glass plate, followed by forming the resin layer.

The resin layer may be formed on the whole of the one surface of the glass plate or may be formed only on a part of the one surface of the glass plate.

In the case where the resin layer is formed only on a part of the one surface of the glass plate (e.g. a region except a 20-mm peripheral region of the glass plate), the above-mentioned transfer roller or the like may be brought into contact with the region of the glass plate on which no resin layer is to be formed (e.g. the 20-mm peripheral region of the glass plate).

The thickness of the resin layer may be, for example, 0.1 μm or larger, and is preferably 1 μm or larger, more preferably 10 μm or larger, still more preferably 30 μm or larger. The thickness of the resin layer may be 5,000 μm or smaller, and is preferably 3,000 μm or smaller, more preferably 300 μm or smaller, still more preferably 100 μm or smaller.

In the case where the resin layer consists of two or more layers, it is preferable that the total thickness of the resin layer is in the above-mentioned preferable range.

The resin layer-attached glass plate producing method of the present invention may include a step other than the above-mentioned steps.

For example, a drying step may be conducted between the etching step and the resin layer forming step. The drying step refers to a step of removing liquid droplets which have been adhered to the surface of the glass plate during the etching step. In other words, in the resin layer-attached glass plate producing method of the present invention, the surface of the glass plate may be dried between the etching step and the resin layer forming step.

The method of the drying step is not particularly limited, and can be, for example, supply of a gas to the surface of the glass plate or heating of the glass plate.

In the present specification, the supply of a gas to the surface of the glass plate in the drying step meets the requirement of “without allowing contact of any object other than the resin layer with the one surface”.

Hereinafter, more specific embodiments of the resin layer-attached glass plate producing method of the present invention will be described below.

### Embodiment 1

An embodiment of the resin layer-attached glass plate producing method of the present invention includes: forming a precursor film for an anti-reflection film on a surface of a glass plate; performing physical strengthening treatment on the glass plate with the precursor film for an anti-reflection film formed thereon; applying a chemical-resistant protection film to the surface of the glass plate on which the precursor film was formed; and then, conducting the above-mentioned etching and resin layer forming steps on the glass plate.

In this embodiment, when the physically strengthening treatment is performed on the glass plate with the precursor film for an anti-reflection film formed thereon, the precursor film for an anti-reflection film is heated to form an anti-reflection film.

Further, in this embodiment, the etching is performed only on a surface of the glass plate opposite to the surface to which the chemical-resistant protection film has been applied and on side faces of the glass plate. In the case where the area of the protection film is smaller than the area of the surface of the glass plate, the etching is also performed on a region (e.g. a peripheral region described later) of the surface to which the protection film has not been applied whereby a step portion is formed on the surface of the glass plate as described later.

In this embodiment, the chemical-resistant protection film applied to the glass plate may be peeled off.

In this embodiment, the form of the glass plate is not particularly limited, but the glass plate is preferably of figured glass.

As the chemical-resistant protection film, a known protection film can be used so as to, for example, allow appropriate selection of the resin layer to be formed in the resin layer forming step.

### Embodiment 2

An embodiment of the resin layer-attached glass plate producing method of the present invention includes: providing a chemically strengthened glass plate by performing chemical strengthening treatment on plate glass; applying a chemical-resistant protection film to one surface of the chemically strengthened glass plate; and then, conducting the above-mentioned etching and resin layer forming steps on the chemically strengthened glass plate.

In this embodiment, the etching is performed only on a surface of the chemically strengthened glass plate opposite to the surface to which the chemical-resistant protection film has been applied and on side faces of the glass plate. As in the above Embodiment 1, a step portion may be formed during the etching.

In this embodiment, the chemical-resistant protection film applied to the chemically strengthened glass plate may be peeled off.

In this embodiment, the form of the glass plate is not particularly limited, but the glass plate is preferably of float glass

### Embodiment 3

An embodiment of the resin layer-attached glass plate producing method of the present invention includes: applying a chemical-resistant protection film to a surface of a glass plate; and then, conducting the above-mentioned etching and resin layer forming steps on the glass plate.

In this embodiment, the etching is performed only on a surface of the glass plate opposite to the surface to which the chemical-resistant protection film has been applied and on side faces of the glass plate. As in the above Embodiment 1, a step portion may be formed during the etching.

In this embodiment, the chemical-resistant protection film applied to the glass plate may be peeled off.

In this embodiment, the form of the glass plate is not particularly limited, but the glass plate is preferably of float glass.

### Embodiment 4

An embodiment of the resin layer-attached glass plate producing method of the present invention includes: forming a precursor film for an anti-reflection film on a surface of a glass plate; heating the precursor film to form an anti-protection film; applying a chemical-resistant protection film on the surface of the glass plate on which the anti-reflection film has been formed; and then, conducting the above-mentioned etching and resin layer forming steps on the glass plate.

In this embodiment, the etching is performed only on a surface of the glass plate opposite to the surface to which the chemical-resistant protection film has been applied and on side faces of the glass plate. As in the above Embodiment 1, a step portion may be formed during the etching.

In this embodiment, the chemical-resistant protection film applied to the glass plate may be peeled off.

In this embodiment, the form of the glass plate is not particularly limited, but the glass plate is preferably of float glass.

### Embodiment 5

An embodiment of the resin layer-attached glass plate producing method of the present invention includes conducting the above-mentioned etching and resin layer forming steps on a glass plate without applying a chemical-resistant protection film to the glass plate.

In this embodiment, the etching is performed on both surfaces of the glass plate and on side faces of the glass plate.

In this embodiment, in the resin layer forming step, the resin layer is preferably formed only on one of the surfaces of the glass plate.

In this embodiment, the form of the glass plate is not particularly limited, but the glass plate is preferably of float glass.

### <Resin Layer-Attached Glass Plate>

The resin layer-attached glass plate according to the present invention has a glass plate and a resin layer, wherein the increase amount of the number density of concave portions in at least one surface of the glass plate by an etching test of the glass plate is 10 number/cm² or less.

Details of the etching test will be described later.

The resin layer-attached glass plate of the present invention is obtained by the above-mentioned resin layer-attached glass plate producing method of the present invention.

The resin layer-attached glass plate of the present invention, in which the number density of the concave portions is not increased by the etching test, is considered to have less number of scratches and thus achieve excellent resistant to falling objects.

FIG. 1 is a schematic cross-sectional view illustrating an example of the resin layer-attached glass plate of the present invention.

A resin layer-attached glass plate 30 shown in FIG. 1 has a glass plate 10 and a resin layer 20. Illustrated in FIG. 1 is the example in which the resin layer 20 is provided only on one surface of the glass plate 10. In the resin layer-attached glass plate 30 of FIG. 1, the increase amount of the number density of concave portions in the one surface of the glass plate 10 (on which the resin layer 20 is formed) is 10 number/cm² or less.

The resin layer-attached glass plate of the present invention will be described in detail below.

### [Resin Layer]

The resin layer-attached glass plate of the present invention has a resin layer.

Examples and preferred embodiments of the resin layer provided in the resin layer-attached glass plate of the present invention are the same as those described for the resin layer-attached glass plate producing method of the present invention. Thus, a description of the resin layer will be omitted.

In the resin layer-attached glass plate of the present invention, the resin layer may be formed only on one surface of the glass plate or may be performed on both surfaces of the glass plate.

### [Glass Plate]

The resin layer-attached glass plate of the present invention has a glass plate.

Examples and preferred embodiments of the glass plate provided in the resin layer-attached glass plate of the present invention are the same as those described for the resin layer-attached glass plate producing method of the present invention. Thus, a description of the glass plate will be omitted.

For example, the glass plate provided in the resin layer-attached glass plate of the present invention may be of strengthened glass (e.g. chemically strengthened glass or physically strengthened glass).

In the case where the glass plate provided in the resin layer-attached glass plate is of strengthened glass (e.g. chemically strengthened glass or physically strengthened glass), it is preferable that the glass plate satisfies at least one of the following requirements 1 and 2.

Requirement 1: the depth of layer of compressive stress on one surface side of the glass plate is smaller than the depth of layer of compressive stress on the other surface side of the glass plate.

Requirement 2: the compressive stress on the one surface side of the glass plate is lower than the compressive stress on the other surface side of the glass plate.

As a method of providing the glass plate that satisfies at least one of the requirements 1 and 2, there may be mentioned a method of, when obtaining the strengthened glass, adjusting the conditions of the strengthening treatment respectively on the one surface and the other surface of the glass plate. There may also be mentioned a method of, after obtaining the strengthened glass, laminating a chemical-resistant film onto the other surface of the strengthened glass and removing a layer of predetermined thickness by etching from the one surface of the strengthened glass.

When at least one of the requirements 1 and 2 is satisfied, the other surface side specified in the requirements 1 and 2 is easy to improve in surface strength. When the other surface side is high in surface strength, it becomes less likely that breakage will occur. Thus, the glass plate is preferably used for e.g. the after-mentioned solar cell module with the other surface arranged on the solar cell substrate side.

### [Etching Test]

In the resin layer-attached glass plate of the present invention, the increase amount of the number density of concave portions in at least one surface of the glass plate by the etching test is 10 number/cm² or less.

Here, the etching test is a test of immersing the glass plate in an etching solution containing 5 mass % hydrogen fluoride, 15 mass % hydrogen chloride and 80% water for 10 minutes under a condition that the temperature of the etching solution is set at 25° C.

More specifically, the etching test is carried out by the following procedure.

First, the resin layer is peeled off from the resin layer-attached glass plate. The peeling of the resin layer is done without contacting the later-described number density measurement area of the surface on which the resin layer was present. In the case where the resin layers are formed on both of the surfaces of the glass plate in the resin layer-attached glass plate, the resin layers are peeled off from both of the surfaces.

After the peeling of the resin layer, the glass plate is immersed in the etching solution. The conditions are as mentioned above.

The number density of the concave portions in the one surface of the glass plate is measured before and after the etching test. The measurement of the number density of the concave portions is made at least on the surface of the resin layer-attached glass plate from which the resin layer was peeled off.

The number density of the concave portions in the one surface of the glass plate is measured with an optical microscope. As the optical microscope, a laser scanning microscope (VK-X3000) with a white light interferometry, which is manufactured by KEYENCE CORPORATION, can be used.

More specifically, a 1.5-mm square region is observed, and concave portions having a size of 1 to 100 μm and a depth of 0.01 to 10 μm are counted as the concave portions. The 1.5-mm square region may be observed dividedly. For example, the 1.5-mm square region may be observed by varying the observation position in 250-μm square blocks. Then, the number density of the concave portions in the one surface of the glass plate is determined by dividing the counted number of the concave portions by the measurement area.

The above observation is done repeatedly, while changing the field of view, until the total measurement area reaches 1 cm².

In the case where the increase amount of the number density of the concave portions is observed with the optical microscope, the increase amount of the number density of the concave portions is preferably 10 number/cm² or less, more preferably 5 number/cm² or less. The increase amount of the number density of the concave portions may be 0 number/cm².

Here, concave portions having an aspect ratio of 10 or higher are not included in the above-mentioned concave portions. The aspect ratio refers to the ratio of the maximum size to the minimum size. Further, visible shapes of figured glass are also not included in the above-mentioned concave portions.

Surfaces defining the concave portions are often composed of smooth curves. The outlines of the concave portions often have a substantially circular shape, a substantially oval shape or a combined shape thereof in plan view.

The shape of the concave portions will be described in detail in the later-described Examples.

In the case where concave portions having a size of 5 to 100 μm and a depth of 0.01 to 10 μm are counted as the concave portions to observe the increase amount of the number density of the concave portions, the increase amount of the number density of the concave portions is preferably in the same range as in the case where concave portions having a size of 1 to 100 μm and a depth of 0.01 to 10 μm are counted as the concave portions.

In the case where concave portions having a size of 10 to 100 μm and a depth of 0.01 to 10 μm are counted as the concave portions to observe the increase amount of the number density of the concave portions, the increase amount of the number density of the concave portions is preferably in the same range as in the case where concave portions having a size of 1 to 100 μm and a depth of 0.01 to 10 μm are counted as the concave portions.

In the case where concave portions having a size of 15 to 100 μm and a depth of 0.01 to 10 μm are counted as the concave portions to observe the increase amount of the number density of the concave portions, the increase amount of the number density of the concave portions is preferably in the same range as in the case where concave portions having a size of 1 to 100 μm and a depth of 0.01 to 10 μm are counted as the concave portions.

In the resin layer-attached glass plate of the present invention, the increase amount of the number density of the concave portions in at least one surface by the etching test is 10 number/cm² or less. In the resin layer-attached glass plate of the present invention, both of the increase amount of the number density of the concave portions in one surface by the etching test and the increase amount of the number density of the concave portions in the other surface by the etching test may be 10 number/cm² or less.

The increase amount of the number density is preferably 5 number/cm² or less, more preferably 1 number/cm² or less. The increase amount of the number density may be 0 number/cm²

The measurement of the number density of the concave portions can be also made by the following procedure.

First, white LED light is emitted from the direction of an edge of the glass plate (a plane perpendicular to the one surface). In other words, white LED light is emitted by an edge lighting method. The emission of the white LED light is adjusted in such a manner that the amount of the light on a center part of the one surface of the glass plate is from 150,000 to 190,000 lx.

In the state that the white LED light is emitted to the glass plate under the above conditions, an image of the glass plate is captured by a digital camera from the side of the one surface of the glass plate. The magnification factor of the digital camera used for image capturing is such that 1 pixel is equivalent to 10 μm square. The captured image is processed, by setting the brightness of the highest luminance pixel as 255 and the brightness of the lowest luminance pixel as 0, to obtain a processed image.

Then, a 27-mm square region is selected as an inspection range on the processed image. In the selected region, a portion in which three or more pixels in the vertical direction and three or more pixels in the horizontal direction, each having a brightness of 40 or higher, are gathered is counted as a concave portion. The number of concave portions in the selected region is counted, and the number density of the concave portions in the one surface of the glass plate is determined by dividing the counted number of the concave portions by the area of the selected region.

The processed image obtained by the above procedure is binarized to obtain a binarized image by setting the pixels lower than or equal to the brightness threshold to 0 (black) and setting the pixels higher than the brightness threshold to 1 (white) provided that the brightness threshold is 127. In the obtained binarized image, the ratio of the number of the white pixels to the number of the black pixels (hereinafter also referred to as the “white pixel ratio”) may be calculated.

The white pixel ratio is preferably 0.20% or lower, more preferably 0.10% or lower, still more preferably 0.05% or lower. The white pixel ratio may be 0.00%.

The resin layer-attached glass plate of the resent invention may have another glass plate. The another glass plate is arranged on, for example, the resin layer side of the resin layer-attached glass plate of the present invention.

### <Applications of Resin Layer-Attached Glass Plate>

The resin layer-attached glass plate obtained by the resin layer-attached glass plate producing method of the present invention and the resin layer-attached glass plate of the present invention are usable for various applications. Among others, the resin layer-attached glass plate of the present invention is useful as various cover glasses because of its excellent resistance to falling objects. The resin layer-attached glass plate of the present invention is particularly preferably usable as a member of a solar cell module. Since the resin layer-attached glass plate of the present invention has excellent resistance to falling objects, the thus-obtained solar cell module is favorable in that breakage is less likely to occur even by collision with e.g. falling objects such as hail.

The solar cell module is not particularly limited except that the resin layer-attached glass plate of the present invention is used, and can adopt a known configuration. For example, the solar cell module may have a configuration in which the resin layer-attached glass plate of the present invention as a light receiving plate and a solar cell substrate are provided in this order. The configuration of the solar cell module other than the above can be a known configuration.

In the case where the resin layer-attached glass plate of the present invention is used in the solar cell module, it is preferable that the resin layer side of the resin layer-attached glass plate (the surface in which the increase amount of the number density of the concave portions is 10 number/cm² or less) is arranged on the solar cell substrate side of the solar cell module.

Further, in the solar cell module, an anti-reflection film may be formed on the side of the resin layer-attached glass plate of the present invention opposite to the solar cell substrate side. In the solar cell module, an anti-glare film may be formed on the side of the resin layer-attached glass plate of the present invention opposite to the solar cell substrate side.

In addition, the solar cell module may include another glass plate (back surface-side glass plate) on a surface of the solar cell substrate opposite to the resin layer-attached glass plate. The back surface-side glass plate may be the resin layer-attached glass plate of the present invention, may be the later-described glass plate of the present invention, or may be a conventionally known glass plate. The back surface-side glass plate may be a glass plate obtained by removing the resin layer from the resin layer-attached glass plate.

The solar cell module may be provided with the use of a glass plate obtained by removing the resin layer from the resin-layer attached glass plate as will be described later.

The resin layer-attached glass plate of the present invention is also usable for other applications and, for example, is applicable as a window glass, a glass for greenhouse, a laminated glass and the like.

### <Glass Plate>

The glass plate according to the present invention has concave portions with a size of 1 to 100 μm and a depth of 0.01 to 10 μm at 0.1 number/cm² or more in at least one surface of the glass plate. In the glass plate of the present invention, the concave portions are preferably present at 1 number/cm² or more, more preferably 50 number/cm² or more, still more preferably 100 number/cm² or more, particularly preferably 200 number/cm² or more. In the glass plate of the present invention, the upper limit of the number density of the concave portions is not particularly limited, and is often 1,000 number/cm² or less.

The measurement of the number density of the concave portions can be made by the same measurement method as the above-mentioned method for measurement of the number density of the concave portions in the resin layer-attached glass plate of the present invention with the use of an optical microscope (a laser scanning microscope with a white light interferometry). In other words, the definition of the concave portions is the same as that in the resin layer-attached glass plate of the present invention.

The number density of the concave portions with a size of 5 to 100 μm and a depth of 0.01 to 10 μm is preferably in the same range as that of the concave portions with a size of 1 to 100 μm and a depth of 0.01 to 10 μm.

Further, the number density of the concave portions with a size of 10 to 100 μm and a depth of 0.01 to 10 μm is preferably in the same range as that of the concave portions with a size of 1 to 100 μm and a depth of 0.01 to 10 μm.

Furthermore, the number density of the concave portions with a size of 15 to 100 μm and a depth of 0.01 to 10 μm is preferably in the same range as that of the concave portions with a size of 1 to 100 μm and a depth of 0.01 to 10 μm.

In the glass plate of the present invention, it is also preferable that the increase amount of the number density of the concave portions in the one surface by an etching test is 10 number/cm² or less.

Here, the etching test is a test of immersing the glass plate in an etching solution containing 5 mass % hydrogen fluoride, 15 mass % hydrogen chloride and 80 mass % water for 10 minutes under a condition that the temperature of the etching solution is set at 25° C.

Since embodiments of the glass plate of the present invention are the same as the embodiments of the resin layer-attached glass plate (see FIG. 1) of the present invention except that no resin layer is formed, a description of the glass plate of the present invention will be omitted. For example, the glass plate of the present invention may be of chemically strengthened glass or physically strengthened glass. Also, it is preferable to satisfy at least one of the above-mentioned requirements 1 and 2.

The glass plate of the present invention is obtained by, for example, removing the resin layer from the resin layer-attached glass plate of the present invention. The removal of the resin layer is preferably done without substantially no increase of scratches on the surface of the glass plate on which the resin layer has been arranged.

The glass plate of the present invention may be obtained by performing etching treatment on plate glass. Since the method of etching treatment is the same as that for the embodiments of the resin layer-attached glass plate of the present invention, a description of the etching method will be omitted. By the etching treatment, the above-mentioned concave portions are formed in at least one surface of the glass plate. In other words, a glass plate, when having the above-mentioned concave portions formed in at least one surface thereof by etching treatment, is regarded as the glass plate of the present invention even without the formation and removal of a resin layer.

As in the case of the resin layer-attached glass plate of the present invention, the glass plate of the present invention has excellent resistance to falling objects.

### <Applications of Glass Plate>

The glass plate of the present invention is usable for various applications. Among others, the glass plate of the present invention is useful as various cover glasses because of its excellent resistance to falling objects. The glass plate of the present invention is particularly preferably usable as a member of a solar cell module. Since the glass plate of the present invention has excellent resistance to falling objects, the thus-obtained solar cell module is favorable in that breakage is less likely to occur even by collision with e.g. falling objects such as hail.

The solar cell module is not particularly limited except that the glass plate of the present invention is used, and can adopt a known configuration. For example, the solar cell module may have a configuration in which the glass plate of the present invention as a light receiving plate and a solar cell substrate are provided in this order. The configuration of the solar cell module other than the above can be a known configuration.

In the case where the glass plate of the present invention is used in the solar cell module, it is preferable that the surface of the glass plate in which the increase amount of the number density of the concave portions by the etching test is 10 number/cm² or less is arranged on the solar cell substrate side of the solar cell module.

Further, in the solar cell module, an anti-reflection film may be formed on the surface of the glass plate of the present invention opposite to the solar cell substrate side. In the solar cell module, an anti-glare film may be formed on the surface of the glass plate of the present invention opposite to the solar cell substrate side.

The glass plate of the present invention is also usable for other applications and, for example, is applicable as a window glass, a glass for greenhouse, a laminated glass and the like.

### <Solar Cell Module>

An embodiment of the solar cell module according to the present invention has a glass plate and a solar cell substrate, wherein the glass plate is of physically strengthened glass, and wherein the glass plate has concave portions with a size of 1 to 100 μm and a depth of 0.01 to 10 μm at 0.1 number/cm² or more in a solar cell substrate-side surface thereof.

The number density of the concave portions in the solar cell substrate-side surface of the glass plate is measured by the same measurement method as the above-mentioned method for measurement of the number density of the concave portions in the resin layer-attached glass plate of the present invention with the use of an optical microscope (a laser scanning microscope with a white light interferometry).

Here, preferred embodiments of the glass plate in the solar cell module are the same as the preferred embodiments of the glass plate of the present invention.

Since embodiments of the solar cell module of the present invention and embodiments of the other members provided in the solar cell module of the present invention are the same as those described above in the section of the applications of the resin layer-attached glass plate, a description of the solar cell module will be omitted.

For example, the solar cell module may include another glass plate (back surface-side glass plate) on a surface of the solar cell substrate opposite to the glass plate. The back surface-side glass plate may be a conventionally known glass plate, or may be a glass plate similar to the glass plate having the predetermined concave portions as in the embodiment of the solar cell module of the present invention. The back surface-side glass plate may be the resin layer-attached glass plate of the present invention, or may be the glass plate of the present invention.

FIG. 2 is a schematic cross-sectional view illustrating an example of the solar cell module of the present invention.

A solar cell module 50 shown in FIG. 2 has a light receiving surface-side glass plate 12 and a solar cell substrate 40. The solar cell substrate 40 is provided with a light receiving surface 40a and a back surface 40b (a surface opposite to the light receiving surface 40a). In FIG. 2, the light receiving surface-side glass plate 12 is arranged on the light receiving surface 40a side of the solar cell substrate 40.

Here, the light receiving surface-side glass plate 12 has the above-mentioned concave portions formed at 0.1 number/cm² or more in the solar cell substrate 40 side surface thereof.

FIG. 3 is a schematic cross-sectional view illustrating another example of the solar cell module of the present invention.

A solar cell module 50a shown in FIG. 3 has a light receiving surface-side glass plate 12, a solar cell substrate 40 and a back surface-side glass plate 14 in this order. The solar cell substrate 40 is provided with a light receiving surface 40a and a back surface 40b as mentioned above. The light receiving surface-side glass plate 12 is arranged on the light receiving surface 40a side of the solar cell substrate 40. The back surface-side glass plate 14 is arranged on the back surface 40b side of the solar cell substrate 40.

As in the case of the above example, the light receiving surface-side glass plate 12 has the above-mentioned concave portions formed at 0.1 number/cm² or more in the solar cell substrate 40 side surface thereof.

The back surface-side glass plate 14 may be formed with a hole as will be described later.

Although the solar cell substrate 40 and the light receiving surface-side glass plate 12 are arranged adjacent to each other in the example of FIG. 3, another configuration may be provided between the solar cell substrate 40 and the light receiving surface-side glass plate 12.

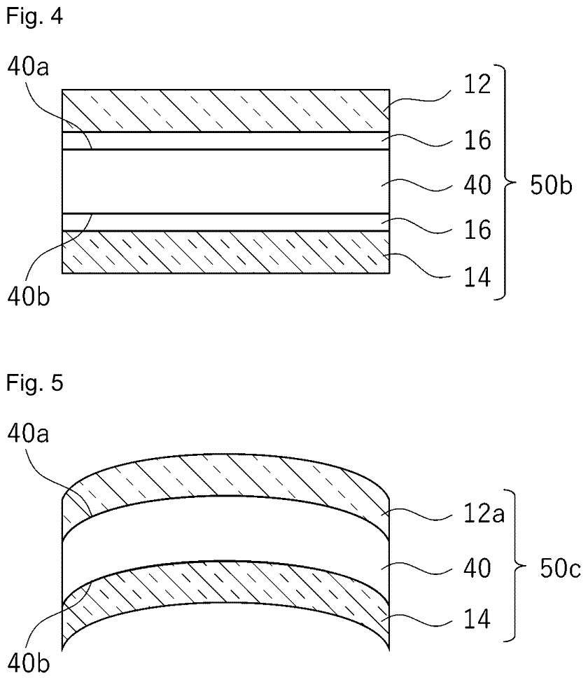

The another configuration is not particularly limited, and can be the above-mentioned resin layer (preferably, pressure sensitive adhesive layer or adhesive layer). FIG. 4 is a schematic cross-sectional view illustrating a modification of the another example of the solar cell module.

A solar cell module 50b shown in FIG. 4 has a light receiving surface-side glass plate 12, a resin layer 16, a solar cell substrate 40, a resin layer 16 and a back surface-side glass plate 14 in this order. As mentioned above, the solar cell substrate 40 is provided with a light receiving surface 40a and a back surface 40b; and the light receiving surface-side glass plate 12 is arranged on the light receiving surface 40a side of the solar cell substrate 40. Further, the back surface-side glass plate 14 is arranged on the back surface 40b side of the solar cell module 40.

In the case where a resin layer is provided, the above-mentioned resin-attached glass plate of the present invention may be used; or a resin layer may be formed separately on the glass plate of the present invention.

Examples of the resin layer are as described above. The resin layer may be a pressure sensitive adhesive layer or an adhesive layer. The resin layers 16 shown in FIG. 4 may be the same type of resin layer or may be different types of resin layers.

Two or more resin layers 16 may be provided between the solar cell substrate 40 and the light receiving surface-side glass plate 12. Two or more resin layers 16 may be provided between the solar cell substrate 40 and the back surface-side glass plate 14.

Furthermore, there may be mentioned an embodiment of the solar cell module of the present invention, which has: a solar cell substrate with a light receiving surface and a back surface opposite to the light receiving surface; and a glass plate arranged on the light receiving surface side of the solar cell substrate, wherein the glass plate satisfies at least one of the following requirements A1, A2 and A3.

Requirement A1: the depth of layer of compressive stress on the solar cell substrate side of the glass plate is smaller than the depth of layer of compressive stress on the side of the glass plate opposite to the solar cell substrate side.

Requirement A2: the compressive stress on the solar cell substrate side of the glass plate is lower than the compressive stress on the side of the glass plate opposite to the solar cell substrate side.

Requirement A3: the glass plate is warped in a convex shape toward the side opposite to the solar cell substrate side.

The above requirement A1 corresponds to the embodiment of the glass plate of the present invention in which: the above-mentioned requirement 1 is satisfied; and the smaller compressive stress layer depth side of the glass plate is arranged on the solar cell substrate side.

The above requirement A2 corresponds to the embodiment of the glass plate of the present invention in which: the above-mentioned requirement 2 is satisfied; and the lower compressive stress side of the glass plate is arranged on the solar cell substrate side.

Regarding the above requirement A3, when the glass plate is warped, stresses exerted on both surfaces of the glass plate are different from each other, and the compressive stress on the convex surface side is often higher. For example, the glass plate of the present invention satisfying at least one of the above-mentioned requirements 1 and 2 could be warped in a convex shape toward the higher compressive stress side. In other words, when the requirement A3 is satisfied, the compressive stress on the side of the glass plate opposite to the solar cell substrate side is often higher than that on the solar cell substrate side of the glass plate.

FIG. 5 schematically shows an embodiment in which the above requirement A3 is satisfied. FIG. 5 is a schematic cross-sectional view illustrating an example of the solar cell module in which the above requirement A3 is satisfied. Here, the scale of illustration in FIG. 1 has been exaggerated for the purposes of explanation.

A solar cell module 50c shown in FIG. 5 has a light receiving surface-side glass plate 12a, a solar cell substrate 40 and a back surface-side glass plate 14 in this order. The solar cell substrate 40 is provided with a light receiving surface 40a and a back surface 40b. The light receiving surface-side glass plate 12 is arranged on the light receiving surface 40a side of the solar cell substrate 40. The back surface-side glass plate 14 is arranged on the back surface 40b side of the solar cell substrate 40.

In this example, the light receiving surface-side glass plate 12a satisfies the above requirement A3. In other words, the light receiving surface-side glass plate 12a is warped in a convex shape toward the side opposite to the solar cell substrate 40 side. In FIG. 5, the solar cell module 50c is entirely warped due to warpage of the light receiving surface-side glass plate 12a.

In the example of FIG. 5, the light receiving surface-side glass plate 12a is warped in a convex shape toward the side opposite to the solar cell substrate 40 side so that, when the light receiving surface-side glass plate 12a is placed with its convex-shaped surface directed toward the ground (toward the direction of gravity), an edge of the light receiving surface-side glass plate 12a is spaced apart from the placement surface. Such spacing between the edge of the light receiving surface-side glass plate 12a and the placement surface leads to improvement in workability.

In the example of FIG. 5, the back surface-side glass plate 14 may further satisfy the above requirement A3.

Examples of the glass plate satisfying the requirements A1, A2 and A3 include the glass plate of the present invention and the resin layer-attached glass plate of the present invention.

In the embodiment of the solar cell module of the present invention, the glass plate may satisfy two or more of the requirements A1, A2 and A3 and may satisfy these three requirements.

In the embodiment of the solar cell module of the present invention, at least a part of a peripheral edge region of the glass plate may preferably be reduced in thickness to form a step portion on the surface of the glass plate opposite to the solar cell substrate. The step portion is preferably smaller in thickness than a center part of the glass plate.

The step portion will be described below with reference to the drawings.

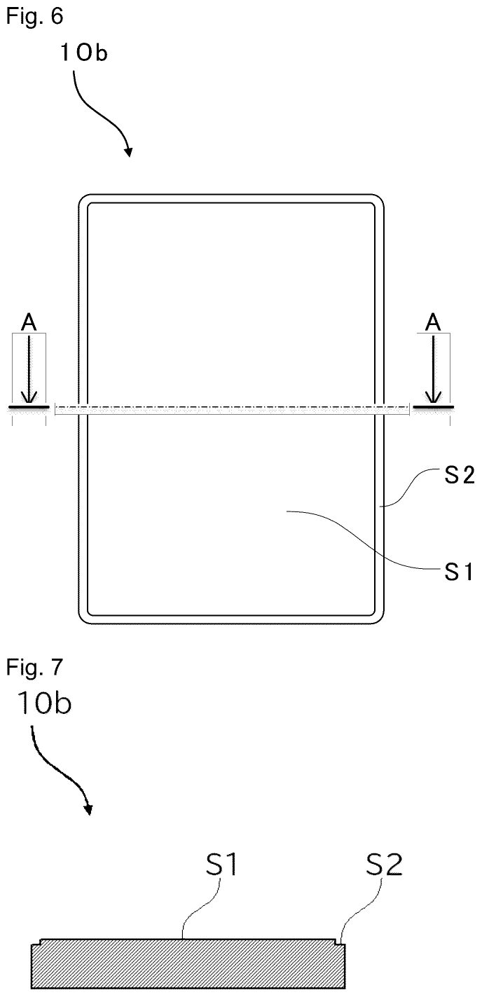

FIG. 6 is a top view illustrating a glass plate 10b usable in the embodiment of the solar cell module of the present invention, in which a peripheral edge region of the glass plate is reduced in thickness to form a step portion.

The glass plate 10b has a main surface S1 located inward of the peripheral edge region of the glass plate 10b and a step portion S2 located on the peripheral edge region.

FIG. 7 is a cross-sectional view of the glass plate 10b as taken along line A-A of FIG. 6.

As shown in FIG. 7, the step portion S2 is smaller in thickness than the portion defining the main surface S1.

Although the step portion S2 is formed on the entire peripheral edge region of the glass plate 10b in FIGS. 6 and 7, the step portion S2 may be formed on a part of the peripheral edge region of the glass plate 10b.

The glass plate with the above step portion can be produced by, for example, the above-mentioned Embodiments 1 to 4 of the resin layer-attached glass plate producing method of the present invention. More specifically, in the above-mentioned Embodiments 1 to 4 in which the chemical-resistant protection film is applied to one surface of the glass plate and then the etching step is conducted, the protection film used is made smaller in size than the outer shape of the glass plate. In other words, the etching step is conducted in a state that the protection film is applied to the main surface of the glass plate without being applied to the peripheral edge region of the glass plate.

When the etching step is conducted in the above-mentioned state, the region (peripheral edge portion) on which no protection film is present undergoes etching in the same manner as the surface on which the protection film is not applied, whereby the step portion is formed. By peeling off the protection film after the etching, the glass plate with the step portion as shown in FIGS. 6 and 7 is obtained.

The glass plate with the step portion may be produced by a method other than the above-mentioned method, but in the case where the glass plate with the step portion is produced by the above-mentioned method, the surface on which no step portion is formed (in FIG. 7, the lower side of the paper) is preferably arranged on the solar cell substrate side.

The glass plate with the step portion often satisfies at least one of the requirements A1, A2 and A3.

In the case where the glass plate with the step portion as shown in FIGS. 6 and 7 is used as the light receiving surface-side glass plate in the solar cell module of the present invention, the surface on which the step portion is formed is preferably arranged on the side opposite to the solar cell substrate side.

In the case where the glass plate with the step portion is used as the back surface-side glass plate in the solar cell module of the present invention, the surface on which the step portion is formed is arranged on the solar cell substrate side.

Specific embodiments of the solar cell module of the present invention to which the glass plate with the step portion is applied will be described below with reference to the drawings.

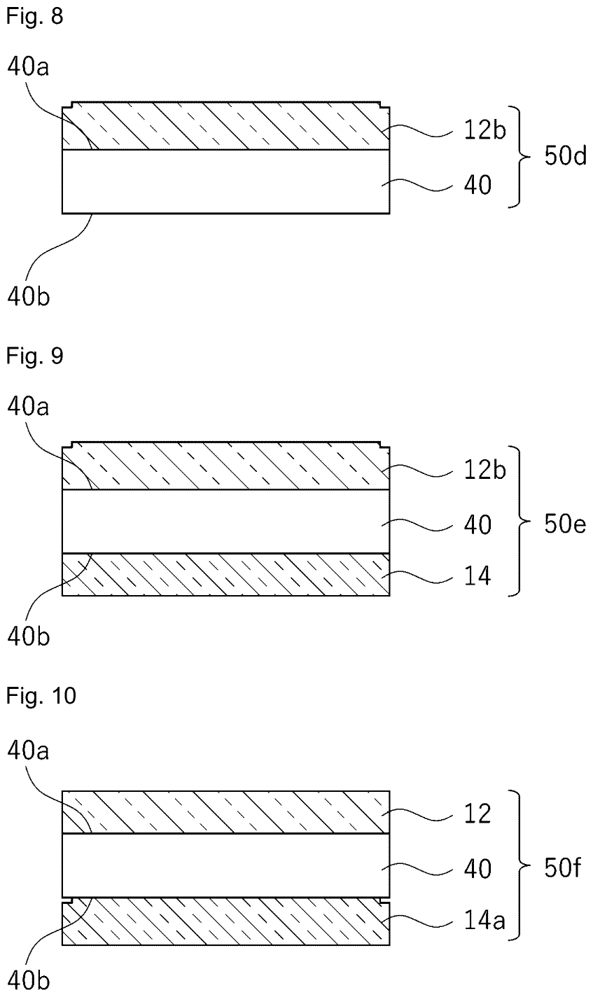

FIG. 8 is a schematic cross-sectional view illustrating an embodiment of the solar cell module in which the glass plate with the step portion is used as the light receiving surface-side glass plate.

In the embodiment of FIG. 8, the solar cell substrate 40 is provided with a light receiving surface 40a and a back surface 40b; and the light receiving surface-side glass plate 12b is arranged on the light receiving surface 40a side of the solar cell substrate 40. As mentioned above, the light receiving surface-side glass plate 12b is formed with a step portion.

FIG. 9 is a schematic cross-sectional view illustrating a modified example of the embodiment of the solar cell module in which the glass plate with the step portion is used as the light receiving surface-side glass plate. The example of FIG. 9 is different from that of FIG. 8 in that the back surface-side glass plate 14 is arranged on the back surface 40b side of the solar cell substrate 40. Since the other configuration of the solar cell module is the same as that of FIG. 8, a description thereof will be omitted. In FIG. 9, the back surface-side glass plate 14 may be the glass plate with the step portion.

In the case where the glass plate with the step portion is used as the back surface-side glass plate, the surface on which the step portion is formed is preferably arranged on the solar cell substrate side.

Specific embodiments of the solar cell module of the present invention in which the glass plate with the step portion is applied as the back surface-side glass plate will be described detail below with reference to the drawings.

FIG. 10 is a schematic cross-sectional view illustrating an embodiment of the solar cell module in which the glass plate with the step portion is used as the back surface-side glass plate. In the embodiment of FIG. 10, the solar cell substrate 40 is provided with a light receiving surface 40a and a back surface 40b; and the back surface-side glass plate 14a is arranged on the back surface 40b side of the solar cell substate 40. As mentioned above, the back surface-side glass plate 14a is formed with a step portion, the surface on which the step portion is formed is arranged on the solar cell substrate 40 side. Further, the light receiving surface-side glass plate 12 is arranged on the light receiving surface 40a side of the solar cell substrate 40.

In the embodiments of FIGS. 8 to 10, the above-mentioned resin layer may be provided at least one of locations between the light receiving surface-side glass plate and the solar cell substrate and between the back surface-side glass plate and the solar cell substrate (see FIG. 4).

Since preferred embodiments of the resin layer are the same as those in the embodiment of FIG. 4, a description of the resin layer will be omitted.

### <Method for Producing Solar Cell Module>

The method for producing a solar cell module according to the present invention includes performing etching and cleaning on at least one surface of a glass plate, and then, arranging a solar cell substrate on the one surface.

By the solar cell module producing method of the present invention, the solar cell module is obtained in which, because of the glass plate having excellent resistance to falling objects, breakage is less likely to occur even by collision with falling objects such as hail.

Since embodiments of the solar cell module of the present invention and embodiments of the other member provided in the solar cell module of the present invention are the same as those described above in the section of the applications of the resin layer-attached glass plate, a description of the solar cell module will be omitted.

For example, the solar cell module may include another glass plate on a surface of the solar cell substrate opposite to the above-mentioned glass plate. The another glass plate may be a conventionally known glass plate, or may be a glass plate similar to the glass plate having the predetermined concave portions as in the embodiment of the solar cell module of the present invention. The another glass plate may be the resin layer-attached glass plate of the present invention, or may be the glass plate of the present invention.

An embodiment of the solar cell module producing method of the present invention may be an embodiment in which a solar cell substrate having a light receiving surface and a back surface opposite to the light receiving surface is used. More specifically, the solar cell module may be produced by providing a solar cell module with a light receiving surface and a back surface opposite to the light receiving surface, arranging a light receiving surface-side glass plate on the light receiving surface and arranging a back surface-side glass plate on the back surface.

In this embodiment of the solar cell module producing method of the present invention, etching and cleaning are performed on at least one of a solar cell substrate-side surface of the light receiving surface-side glass plate and a surface of the back surface-side glass plate opposite to the solar cell substrate.

Each of the light receiving surface-side glass plate and the back surface-side glass plate may be the resin layer-attached glass plate of the present invention or may be the glass plate of the present invention.

In the embodiment of the solar cell module producing method of the present invention, it is also preferable to perform etching and cleaning on the back surface-side glass plate with a hole formed therein. In other words, in the embodiment of the solar cell module producing method of the present invention, a hole may be formed in a part of the back surface-side glass plate. The hole may preferably be used as a hole for pulling wiring on the solar cell substrate out of the solar cell module. Here, the hole refers to a space that passes through the glass plate in its thickness direction.

Specific examples of the back surface-side glass plate formed with a hole and subjected to etching and cleaning will be described below with reference to the drawings.

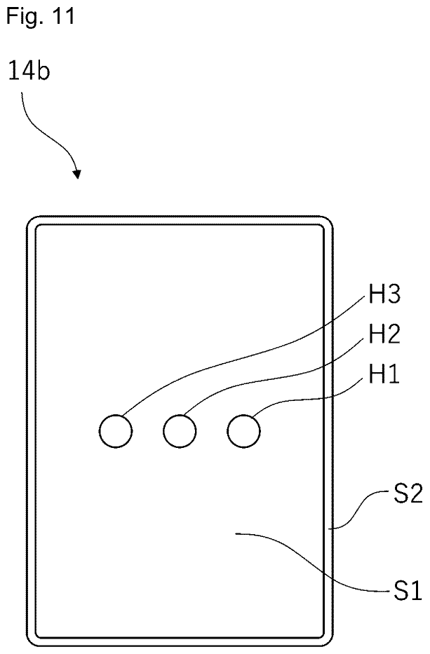

FIG. 11 is a top view illustrating an example of the back surface-side glass plate with holes. A back surface-side glass plate 14b shown in FIG. 11 has circular holes H1, H2 and H3. Further, the back surface-side glass plate 14b has a main surface S1 and a step portion S2. For example, the back surface-side glass plate 14b can be obtained by, after forming circular holes H1, H2 and H3 in a glass plate, applying the above-mentioned chemical-resistant protection film of smaller size than the outer shape of the glass plate to one surface of the glass plate and conducting the etching step on the glass plate.

Although three holes are formed in the example of FIG. 11, the arrangement of holes in the back surface-side glass plate is not particularly limited. Only one hole may be formed, or two or more holes may be formed. The shape of the hole is not limited to the circular shape and can be, for example, a rectangular shape, an elongated circular shape or an oval shape.

The size of the hole in the in-plane direction of the back surface-side glass plate is not particularly limited. In the case where the hole is circular in shape, for example, the diameter of the hole may be 5 mm or larger, may be 10 mm or larger or may be 20 mm or larger. The upper limit of the diameter of the hole is not particularly limited, and can be, for example, 100 mm or smaller.

Although the step portion S2 is provided in the example of FIG. 11, the back surface-side glass plate may have a hole or holes with no step portion S2.

In the case where the back surface-side glass plate has a hole as mentioned above, the back surface-side glass plate is preferably subjected to etching after the formation of the hole so that a side part of the hole can also be etched.

Also, it is preferable to arrange the solar cell substrate on one surface of the glass plate, without substantially increasing scratches on the one surface, after the etching and cleaning.

Regarding the glass plate, “without substantially increasing scratches on one surface” has the same meaning as that defined in the resin layer forming step of the resin layer-attached glass plate producing method of the present invention. In other words, “without substantially increasing scratches on one surface” means that the increase amount of the number density of the concave portions in the one surface by an etching test of the glass plate is 10 number/cm² or less with no increase of visible scratches. The increase amount of the number density of the concave portions is preferably 5 number/cm² or less, more preferably 1 number/cm² or less. The increase amount of the number density of the concave portions may be 0 number/cm² or more.

The etching and cleaning in the solar cell module producing method of the present invention can be performed in the same manner as in the etching step of the above-mentioned resin layer-attached glass plate producing method of the present invention.

The solar cell module producing method of the present invention may include the above-mentioned resin layer-attached glass plate producing method of the present invention.

More specifically, the solar cell module producing method of the present invention may include any of Embodiments 1 to 5 of the resin layer-attached glass plate producing method of the present invention.

Further, the solar cell module producing method of the present invention may include a step of peeling the resin layer from the resin layer-attached glass plate obtained by the resin layer-attached glass plate producing method. The peeling of the resin layer is preferably carried out before the later-described assembling step.

The solar cell module producing method of the present invention may be carried out by conducting the etching step on the glass plate as described in the resin layer-attached glass plate producing method, and then, conducting the below-described assembling step without forming a resin layer on the etched glass plate.

The solar cell module producing method of the present invention may include an assembling step. The assembling step refers to a step of assembling the solar cell module and, more specifically, a step including laminating the glass plate onto the solar cell substrate.

In this step, the glass plate is arranged such that the one surface (etched and cleaned surface) of the glass plate is directed to the solar cell substrate side.

As a specific example of the assembling step, there may be mentioned a step of applying an adhesive film to the solar cell substrate, laminating the glass plate to the adhesive film and performing autoclave treatment.

As another specific example of the assembling step, there may be mentioned a step of applying an adhesive film to the glass plate, laminating the solar cell substrate to the adhesive film and performing autoclave treatment.

In the assembling step, the glass plate may be laminated to only one surface of the solar cell substrate, or the glass plates may be laminated to both surfaces of the solar cell substrate. In other words, the assembling step may be a step of arranging a first adhesive film on the first glass plate, placing the solar cell substrate on a side of the first adhesive film opposite to the first glass plate, arranging a second adhesive film on a side of the solar cell substrate opposite to the first glass plate and arranging the second glass plate on a side of the second adhesive film opposite to the solar cell substrate.

Here, at least one of the first glass plate and the second glass plate is the glass plate on which the etching and cleaning have been performed. In the case where each of the first glass plate and the second glass plate is the glass plate of the present invention, it is preferable that: the etched surface of the first glass plate is arranged on the solar cell substrate side; and the etched surface of the second glass plate is arranged on the side opposite to the solar cell substrate side. The other of the first glass plate and the second glass plate may be a glass plate without etching.

In the above-mentioned examples, the autoclave treatment may be performed after obtaining the laminate of the first glass plate, the first adhesive film, the solar cell substrate, the second adhesive film and the second glass plate.

The adhesive film (including the first adhesive film and the second adhesive film) used in the assembling step can be a conventionally known adhesive film. For example, a pressure sensitive adhesive layer or adhesive layer as described in the resin layer-attached glass plate producing method of the present invention can be used. The adhesive film is preferably a film made of, for example, an ethylene-vinyl acetate resin.

The assembling step may include still another operation.

For example, the assembling step may include attachment of a peripheral frame after the autoclave treatment. The assembling step may also include connection of wiring.

Further, at least one of quality inspection and packaging may be included.

### EXAMPLES

Hereinafter, the present invention will be described in more detail below based on the following Examples.

The materials, amounts used, proportions, treatment operations, and treatment procedures shown in the following Examples can be modified as appropriate without departing from the gist of the present invention. Therefore, the scope of the present invention should not be interpreted limitedly to the following Examples.

In the following, Ex. 1, Ex. 3 to Ex. 5, Ex. 7, Ex. 8, Ex. 10, Ex. 11, Ex. 13 to Ex. 16, Ex. 18 and Ex. 20 are Examples of the present invention; and Ex. 2, Ex. 6, Ex. 9, Ex. 12, Ex. 17 and Ex. 19 are Comparative Examples.

### <Ex. 1>

### [Production of Resin Layer-Attached Glass Plate]

Glass raw materials were mixed to obtain the following composition as expressed in mole percentage on the oxide basis, and then, melted by heating into a molten glass. The molten glass was formed into a plate-shaped glass ribbon by a float process. The glass ribbon was annealed in an annealing furnace, thereby obtaining a glass plate with a thickness of 0.7 mm.

Glass material A: SiO₂: 64.5%, Al₂O₃: 8.0%, Na₂O: 12.5%, K₂O: 4.0%, MgO: 10.5% and ZrO₂: 0.5%.

The above-obtained glass plate was subjected to etching treatment by immersion in an etching solution of the following composition. More specifically, the etching treatment was performed by adjusting the immersion time such that the amount of etching became 75 μm on each side of the glass plate.

The etching solution used contained 5 mass % hydrogen fluoride, 15 mass % hydrogen chloride and 80 mass % water.

After the etching treatment, both of the surfaces of the glass plate were cleaned with ion-exchanged water. The cleaning was performed by supplying the ion-exchanged water to the surfaces of the glass plate through a shower. After the cleaning, the glass plate was dried.

Here, the size and depth of concave portions in the surface of the glass plate after the etching were measured by the above-mentioned method. FIG. 14 is a schematic view illustrating a microscopic observation image of the concave portions after the etching. In FIG. 14, the outlines of the concave portions after the etching are shown. In the schematic view of the microscopic observation image of FIG. 14, concave portions C1, C2, C3 and C4 are shown.

The outline of the concave portion C1 has a substantially circular shape with a diameter d1. The outline of the concave portion C2 has a substantially oval shape with a diameter (maximum diameter) d2 in its longer diameter direction.

Further, the outlines of the concave portions C3 and C4 are combined together to define a combined shape. In FIG. 14, the interpolation lines of the outlines of the concave portions C3 and C4 are respectively indicated by dotted lines. The interpolated outlines of the concave portions C3 and C4 are found to be circular in shape. The concave portion C3 has a diameter d3. Similarly, the concave portion C4 has a diameter d4. In the case where the outlines of concave portions are combined together to define a combined shape but can be separated into interpolated shapes as mentioned above, the concave portions are regarded as being separately present and thus are counted separately.

The number of the concave portions observed in the schematic view of the microscopic observation image of FIG. 14 is four. In other words, each of the diameters d1 to d4 is in the range of 1 to 100 μm.

In Table 1, the typical shapes of the concave portions after the etching are shown.

The shapes of the outlines of the concave portions after the etching were substantially circular or substantially oval in plan view. On the other hand, before the etching, the number of the concave portions having a size of 1 to 100 μm, a depth of 0.01 to 10 μm and an aspect ratio of 10 or lower and defined by smooth curves was 0.1 number/cm² or less.

TABLE 1

After etching

| | Diameter [μm] of | Depth [μm] of |
|---|---|---|
| | concave portion | concave portion |
| Concave portion 1 | 33.3 | 0.16 |
| Concave portion 2 | 30.5 | 0.18 |
| Concave portion 3 | 13.8 | 0.17 |

Then, a resin layer was formed on one of the surfaces of the glass plate after the cleaning. Here, the surface on which the resin layer was to be formed was kept from contact with any object other than the resin layer during time from the cleaning of the glass plate until the formation of the resin layer.

As the resin layer, used was SUNYTECT (registered tradename) PAC-3-70 (film thickness: 70 μm) manufactured by Sun A Kaken Co., Ltd. This resin layer was laminated to one of the surfaces of the glass plate after the cleaning.

By the above procedure, a resin layer-attached glass plate of Ex. 1-1 was obtained. Further, a glass plate of Ex. 1-2 was obtained in the same manner as above except that no resin layer was laminated.

### [Rub Test]

Without peeling off the resin layer of the above-obtained resin layer-attached glass plate of Ex. 1-1, a rub test simulating roller conveyance was conducted on the resin layer side of the glass plate. More specifically, the rub test was conducted by, while pressing a #180 SiC sandpaper with a load of 500 g against the resin layer side, stroking the sandpaper five times. In the rub test, the stroke width was set to 20 mm; and the speed was set to 80 times/min. After the test, the resin layer of Ex. 1-1 was peeled off to obtain the glass plate. Likewise, a rub test was conducted on the glass plate of Ex. 1-2.

After the rub test, the surface of the glass plate of Ex. 1-1 on which the resin layer had been present was visually compared with the glass plate of Ex. 1-2, and it was found that the glass plate of Ex. 1-2 had more scratches.

Subsequently, an etching test was conducted on the glass plate under the above-mentioned conditions.

After the etching test, the number density of concave portions in the surface on which the resin layer had been formed was measured by the above-mentioned method. Further, a resin layer-attached glass plate was obtained by the same procedure as above, from which the resin layer was peeled off, and then, the number density of concave portions in the surface on which the resin layer had been formed was measured by the above-mentioned method.

From the measurement results of the number density of the concave portions, the amount by which the number density of the concave portions in the surface on which the resin layer had been formed was increased by the etching test was calculated by the above-mentioned method. The increase amount of the number density was found to be 0 number/cm².

The resin layer-attached glass plate of Ex. 1-1, which had less scratches, was less susceptible to breakage from scratches and thus was excellent in resistance to falling objects.

### <Ex. 2>

First, a molten glass of glass material B was formed by a roll-out process to obtain a figured glass plate with a plate thickness of 3.2 mm. The obtained figured glass plate had a finely uneven embossed surface as one surface and a satin-patterned surface as the other surface. Subsequently, a slightly-adhesive film (the same resin layer as that in Ex. 1) was laminated to the embossed surface. The thus-obtained figured glass plate was used as a glass plate of Ex. 2.

The composition (in mol % on the oxide basis) of the glass material B was as follows.

Glass material B: SiO₂: 71.76%, Al₂O₃: 0.64%, Na₂O: 12.31%, K₂O: 0.06%, MgO: 6.13%, CaO: 8.89%, SO₃: 0.16% and Sb₂O₃: 0.04%.

The above-obtained glass plate was cut into a size of 100 mm×100 mm, and then, introduced into a thermal strengthening tank and subjected to physical strengthening treatment. When the embossed surface side of the physically strengthened glass plate was observed with a laser microscope, scratches were found on the raised portions of the embossed surface but did not correspond to concave portions having a diameter of 1 to 100 μm and a depth of 0.01 to 10 μm and defined by smooth curves. More specifically, the size of scratches on the raised portions of the embossed surface exceeded 100 μm.

The glass plate of Ex. 2 obtained by the above-mentioned procedure was evaluated for the strength against falling objects by the following method. The method for evaluation of the strength against falling objects will be described below with reference to the drawing.

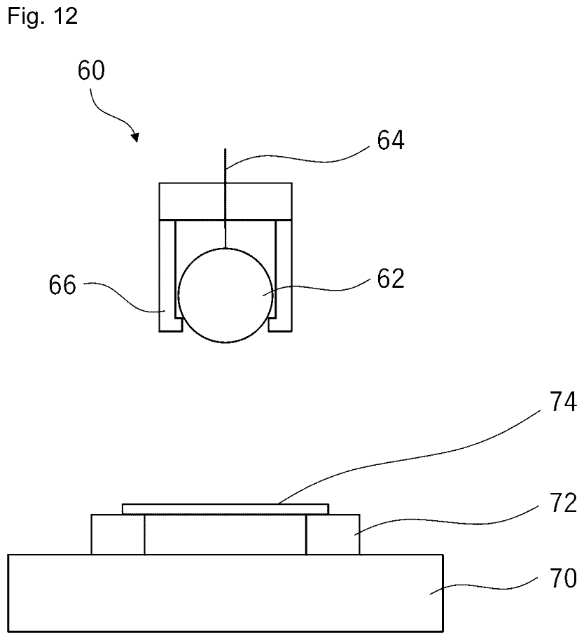

FIG. 12 is a schematic view illustrating a falling ball impact strength tester 60 used for evaluation of the strength against falling objects (falling ball impact strength).

The falling ball impact strength tester 60 shown in FIG. 12 was configured to measure the falling ball impact strength of a sample 74 by dropping a steel ball 62 from a predetermined height toward the sample 74 and bringing the steel ball into collision with the sample 74. The sample 74 was mounted to a frame-shaped resin-made jig 72, and the jig 72 with the sample 74 was placed on a stage 70.

The steel ball 62 was held by a stopper 66 before being dropped. By unlocking the stopper 66, the steel ball 62 was allowed to fall freely. Here, the steel ball 62 was connected to a windable string 64, and the windable string 64 was connected to the body part (not shown) of the falling ball impact strength tester 60. Thus, the steel ball 62 was returned to a predetermined position by winding up the windable string 64.

The stopper 66 was connected to the body part (not shown) of the falling ball impact strength tester 60 so as to adjust the drop height (vertical direction of FIG. 12).

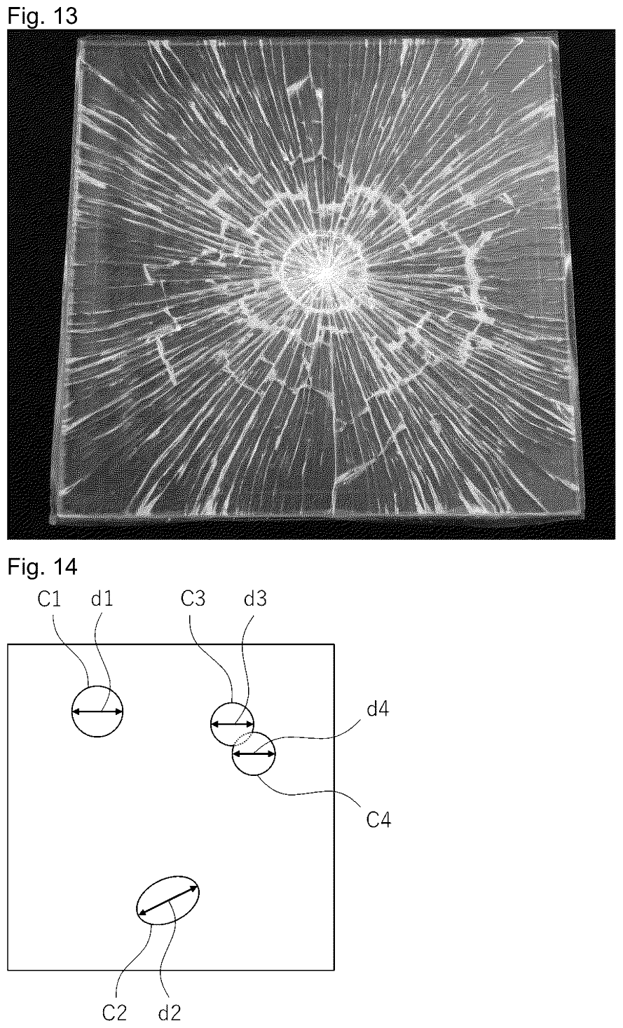

The glass plate of Ex. 2 was set as the sample 74 in the falling ball impact strength tester 60. The steel ball 62 was dropped onto and brought into collision with the sample 74 while changing the drop height. This operation was repeated until cracks (see FIG. 13) occurred in the sample 74. The collision energy (unit: J) at which crack occurred was read as the falling ball impact strength of the sample 74.

The measurement of the falling ball impact strength was made on 10 samples to obtain the maximum, average, minimum and B10 values of the falling ball impact strength. The maximum, average, minimum and B10 values of the falling ball impact strength of the glass plate of Ex. 2 are shown in Table below. Here, the B10 value refers to a falling ball impact strength at which 10% of cracks occur as determined from the Weibull distribution.

The steel ball 62 used had a diameter of 60 mm and a mass of 877 g. Further, the glass plate of Ex. 2 was mounted to the jig 72 such that the embossed surface was arranged on the ground side (the side opposite to the side with which the steel ball 62 was brought into collision).

### <Ex. 3>

A glass plate of Ex. 3 was obtained by providing the glass plate of Ex. 2, subjecting the glass plate to etching treatment and forming the same resin layer as that of Ex. 2 on the glass plate. More specifically, the etching treatment was performed by adjusting the immersion time such that the amount of etching became 50 μm on each side of the glass plate.

The etching solution used contained 5 mass % hydrogen fluoride, 15 mass % hydrogen chloride and 80 mass % water. When the embossed surface of the glass plate was observed after the etching treatment, scratches on the raised portions of the embossed surface were circular or oval concave portions each having a longer diameter of about 10 to 50 μm and a depth of about 0.1 to 0.3 μm. After the etching treatment, the same resin layer as that of Ex. 2 was laminated.

The thus-obtained glass plate of Ex. 3 was evaluated for the strength against falling objects in the same manner as in Ex. 2. The results are shown in Table below.

Here, the resin layer-attached glass plate of the present invention can be obtained by forming the resin layer on at least one surface of the glass plate of Ex. 3 by the above-mentioned procedure

### <Ex. 4>

A glass plate of Ex. 4 was obtained by providing the glass plate of Ex. 3 with no slightly-adhesive resin layer laminated. It was confirmed that, when the glass plate of Ex. 4 was handled by conveyance etc., scratches occurred on the raised portions of the embossed surface.

The obtained glass plate of Ex. 4 was evaluated for the falling ball impact strength in the same manner as in Ex. 2. The results are shown in Table below.

### <Ex. 5>

A figured glass plate having a finely uneven embossed surface as one surface and a satin-like surface (satin-patterned surface) as the other surface was obtained in the same manner as in Ex. 2. The obtained figured glass plate was cut into a size of 1,717 mm×1,128 mm and subjected to chamfering. After that, an anti-reflection coating layer (AR coating layer) containing SiO₂ as a main component was formed on the satin-patterned surface.

Then, a protection film for etching prevention was laminated on the AR coating layer-side of the glass plate. The protection film was shaped to be 5 mm smaller than the edge of the figured glass plate.

The glass plate on which the protection film was laminated was subjected to etching treatment in the same manner as in Ex. 3. After the etching treatment, the protection film was peeled off, and the same resin layer as that of Ex. 2 was formed on the embossed surface. With this, a glass plate of Ex. 5 was obtained. The glass plate of Ex. 5 had a step portion in a peripheral edge region of the satin-patterned surface.

The obtained glass plate of Ex. 5 was evaluated for the falling ball impact strength in the same manner as in Ex. 2. The results are shown in Table below.

### <Ex. 6 to 8>

A molten glass of glass material C was formed by a float process to obtain a float glass plate with a thickness of 2.0 mm. The obtained float glass plate had a smooth surface.

The composition (in mol % on the oxide basis) of the glass material C was as follows.

Glass material C: SiO₂: 68.84%, Al₂O₃: 2.99%, Na₂O: 14.1%, K₂O: 0.2%, MgO: 6.32% and CaO: 7.56%.

The above-obtained glass plate was cut into a size of 100 mm×100 mm, and then, introduced into a thermal strengthening tank and subjected to physical strengthening treatment.

A glass plate of Ex. 6 was obtained by forming a resin layer as mentioned above on the float glass plate immediately after the physical strengthening treatment.

When the surface of the glass plate of Ex. 6 was observed, it was confirmed that linear scratches (not corresponding to the above-defined concave portions) occurred on the glass surface.

A glass plate of Ex. 7 was obtained by performing etching treatment on the float glass plate immediately after the physical strengthening treatment. More specifically, the etching treatment was performed by adjusting the immersion time such that the amount of etching became 10 μm on each side of the glass plate.

The etching solution used contained 5 mass % hydrogen fluoride, 15 mass % hydrogen chloride and 80 mass % water. When the surface of the glass plate was observed after the etching treatment, it was confirmed that the linear scratches was increased in width and had a smooth cross-sectional shape. Further, circular or oval concave portions were also found. These concave portions had a longer diameter of about 5 to 60 μm and a depth of about 0.1 to 10 μm.

A glass plate of Ex. 8 was obtained by forming a resin layer in the same manner as in Ex. 3 on the glass plate of Ex. 7.

It was confirmed that, when the glass plate of Ex. 7 was handled by conveyance etc., there occurred linear scratches as above.

The obtained glass plates of Ex. 6 to 8 were evaluated for the falling ball impact strength in the same manner as in Ex. 2. The results are shown in Table below.

For convenience sake, the glass plates of Ex. 2 to 8 are hereinafter referred to as glass plates B2 to B8, respectively.

### <Ex. 9 to 20>

Solar cell modules were produced using the above-mentioned glass plates and other members, and then, were evaluated for the strength against falling objects. In the following, Ex. 9 will be representatively described below in terms of the methods or production of the solar cell module and the method for evaluation of the strength of the solar cell module against falling objects; and the other examples will be described in terms of the differences from Ex. 9.

The solar cell module of Ex. 9 had a light receiving surface-side glass plate, a solar cell substrate and a back surface-side glass plate in this order. The solar cell module of Ex. 9 was produced by the following procedure.

First, the glass plate B2 was placed on a workbench with the satin-patterned surface of the glass plate directed downward, and the resin layer on the embossed surface side was removed. Next, an adhesive layer of ethylene-vinyl acetate resin was formed on the embossed surface of the glass plate B2. The solar cell substrate of crystalline silicon was stacked on the adhesive layer. Further, an adhesive layer was formed on a side of the solar cell substrate opposite to the glass plate B2 side. A film containing polyethylene terephthalate (PET) resin as a base material (backsheet Appli-Sola (registered tradename) manufactured by KEIWA Inc.) was stacked on a side of the adhesive layer opposite to the solar cell substrate side. Then, autoclave treatment was performed, and a frame was attached. With this, the solar cell module of Ex. 9 was completed.

In the solar cell module of Ex. 9, the glass plate B2, the adhesive layer, the solar cell substrate, the adhesive layer and the PET film were arranged in this order. Here, the surface of the glass plate B2 opposite to the solar cell substrate was the satin-patterned surface.

An ice ball with a diameter of 65 mm was brought into collision, at a speed of 36.7 m/s (89 J), with the glass plate B2 of the solar cell module of Ex. 9 to check the occurrence of breakage in the glass plate. The results are shown in Table below.

The solar cell module of Ex. 10 was produced in the same manner as in Ex. 9 except that the glass plate B3 was used as the light receiving surface-side glass plate, and then, was evaluated in the same manner as above.

The solar cell module of Ex. 11 was produced in the same manner as in Ex. 10 except that a glass plate B9 was used as the back surface-side member, and then, was evaluated in the same manner as above.

The glass plate B9 was a figured glass plate prepared in the same manner as the glass plate B2 except that the thickness of the glass plate was adjusted to 2.0 mm. In the obtained solar cell module of Ex. 11, the satin-patterned surface of the glass plate B9 was arranged on the side opposite to the solar cell substrate side.

The solar cell module of Ex. 12 was produced in the same manner as in Ex. 11 except that the glass plate B9 was used as the light receiving surface-side glass plate. Here, the surface of the glass plate B9 opposite to the solar cell substrate was the satin-patterned surface.

An ice ball with a diameter of 55 mm was brought into collision, at a speed of 33.9 m/s (46 J), with the glass plate B9 on the light receiving surface-side of the solar cell module of Ex. 11 to check the occurrence of breakage in the glass plate. The results are shown in Table below.

The solar cell module of Ex. 13 was produced in the same manner as in Ex. 12 except that a glass plate B10 was used as the light receiving surface-side glass plate, and then, was evaluated in the same manner as in Ex. 12.

The glass plate B10 was prepared by, in the process of preparing the glass plate B9, performing etching treatment under the same conditions as the glass plate B3.

The solar cell module of Ex. 14 was produced in the same manner as in Ex. 13 except that a glass plate B9H, which was prepared by forming three holes with a diameter of 15 mm in a center part of the glass plate B9, was used as the back surface-side glass plate, and then, was evaluated in the same manner as in Ex. 13.

The solar cell module of Ex. 15 was produced in the same manner as in Ex. 14 except that the glass plate B10H on which the etching treatment was performed under the same conditions as the glass plate B10 was used as the back surface-side glass plate, and then, was evaluated in the same manner as in Ex. 14.

Here, in the preparation of the glass plate B10H, the etching treatment was also performed on cross-sectional parts of the holes. The glass plate B10H was arranged such that the satin-patterned surface was on the side opposite to the solar cell substrate side.

The solar cell module of Ex. 16 was produced in the same manner as in Ex. 15 except that a glass plate B11H was used as the back surface-side glass plate, and then, was evaluated in the same manner as in Ex. 15.

The glass plate B11H was prepared by laminating a protection film to the embossed surface of the glass plate B9H in the same manner ss the glass plate B5 and performing etching treatment under the same conditions as the glass plate B10H. In other words, the glass plate B11H had holes and had a step portion on the embossed surface. In the preparation of the glass plate B11H, the etching treatment was also performed on cross-sectional parts of the holes. The glass plate B11H was arranged such that the satin-patterned surface was on the side opposite to the solar cell substrate side.

The solar cell module of Ex. 17 was produced in the same manner as in Ex. 9 except that the glass plate B6 was used as the light receiving surface-side glass plate, and then, was evaluated in the same manner as in Ex. 9.

The solar cell module of Ex. 18 was produced in the same manner as in Ex. 9 except that the glass plate B8 was used as the light receiving surface-side glass plate, and then, was evaluated in the same manner as in Ex. 9.

The solar cell module of Ex. 19 was produced in the same manner as in Ex. 13 except that: a glass plate B12 was used as the light receiving surface-side glass plate; and a glass plate B13 was used as the back surface-side glass plate, and then, was evaluated in the same manner as in Ex. 13.

The glass plate 12 was prepared by, in the process of preparing the glass plate B6, adjusting the thickness of the glass plate to 2.0 mm.

The glass plate B13 was prepared by performing etching treatment on the glass plate B12 under the same conditions as the glass plate B8, followed by forming a resin layer.

The solar cell module of Ex. 20 was produced in the same manner as in Ex. 19 except that: the glass plate B13 was used as the light receiving surface-side glass plate; and a glass plate B13H was used as the back surface-side glass plate.

The glass plate B13H was prepared by, in the process of preparing the glass plate B13, using the glass plate B12 with holes. In the preparation of the glass plate B13H, the etching treatment was also performed on cross-sectional parts of the holes.

It is herein noted that the glass used in Ex. 16 satisfied the requirements A1 to A3.

### <Results>

The conditions for production of each glass plate, and the concave portion number density and falling ball impact strength of each glass as measured by the above-mentioned methods, are shown in Table 2.

Further, the configurations of the respective solar cell modules and the falling ball impact strength evaluation results are shown in Table 3. Here, the light receiving surface-side glass plate and the back surface-side glass plate were evaluated as follows: “A” when no breakage occurred in the glass plate; and “B” when breakage occurred in the glass plate.

TABLE 2

| | | Ex. 2 | Ex. 3 | Ex. 4 | Ex. 5 | Ex. 6 | Ex. 7 | Ex. 8 |
|---|---|---|---|---|---|---|---|---|
| Glass plate | | B2 | B3 | B4 | B5 | B6 | B7 | B8 |
| Glass material | | B | B | B | B | C | C | C |
| Thickness [mm] | | 3.2 | 3.2 | 3.2 | 3.2 | 3.2 | 3.2 | 3.2 |
| Forming process | | Figured | Figured | Figured | Figured | Float | Float | Float |
| Strengthening treatment | | Physical | Physical | Physical | Physical | Physical | Physical | Physical |
| AR coating layer | | — | — | — | Formed | — | — | — |
| Etching amount [μm] | | 0 | 50 | 50 | 50 | 0 | 10 | 10 |
| Number density [number/cm²] | | 0.0 | 210.0 | 288.0 | 267.0 | 0.0 | 0.2 | 0.3 |
| of concave portions | | | | | | | | |
| Resin layer | | Formed | Formed | Not formed | Formed | Formed | Not formed | Formed |
| Falling ball | Maximum value | 1.29 | 25.78 | 13.75 | 15.47 | 5.16 | 18.91 | 22.35 |
| impact | Average value | 1.20 | 13.67 | 7.88 | 11.09 | 3.15 | 10.39 | 15.26 |
| strength [J] | Minimum value | 0.86 | 5.59 | 5.16 | 6.88 | 1.29 | 5.59 | 7.74 |
| | B10 value | 0.85 | 5.57 | 4.61 | 5.13 | 1.44 | 5.06 | 6.32 |

TABLE 3

| | | Ex. 9 | Ex. 10 | Ex. 11 | Ex. 12 | Ex. 13 | Ex. 14 |
|---|---|---|---|---|---|---|---|
| Light | Glass material | B | B | B | B | B | B |
| receiving | Glass plate | B2 | B3 | B3 | B9 | B10 | B10 |
| surface-side | Thickness [mm] | 3.2 | 3.2 | 3.2 | 2.0 | 2.0 | 2.0 |
| glass plate | Strengthening treatment | Physical | Physical | Physical | Physical | Physical | Physical |
| | AR coating layer | Not | Not | Not | Not | Not | Not |
| | | formed | formed | formed | formed | formed | formed |
| | Etching amount [μm] | 0 | 50 | 50 | 0 | 50 | 50 |
| | Number density [number/cm²] | 0.0 | 276.0 | 298.0 | 0.0 | 230.0 | 210.0 |
| | of concave portions | | | | | | |
| | Resin layer | Formed | Formed | Formed | Formed | Formed | Formed |
| Back | Glass material | PET | PET | B | B | B | B |
| surface-side | Glass plate | — | — | B9 | B9 | B9 | B9H |
| glass plate | Thickness [mm] | — | — | 2.0 | 2.0 | 2.0 | 2.0 |
| | Strengthening treatment | — | — | Physical | Physical | Physical | Physical |
| | Etching amount [μm] | — | — | 0 | 0 | 0 | 0 |
| | Etching surface | — | — | — | — | — | — |
| | Number density [number/cm²] | — | — | 0.0 | 0.0 | 0.0 | 0.0 |
| | of concave portions | | | | | | |
| | Hole | — | — | — | — | — | Formed |
| Module | Light receiving surface-side | A | A | A | B | A | A |
| strength | glass plate: 46J | | | | | | |
| test | Light receiving surface-side | B | A | A | — | A | A |
| | glass plate: 89J | | | | | | |
| | Back surface-side glass plate: 46J | — | — | A | B | A | A |
| | Back surface-side glass plate: 89J | — | — | A | — | B | B |
| | | Ex. 15 | Ex. 16 | Ex. 17 | Ex. 18 | Ex. 19 | Ex. 20 |
| Light | Glass material | B | B | C | C | C | C |
| receiving | Glass plate | B10 | B10 | B6 | B8 | B12 | B13 |
| surface-side | Thickness [mm] | 2.0 | 2.0 | 3.2 | 3.2 | 2.0 | 2.0 |
| glass plate | Strengthening treatment | Physical | Physical | Physical | Physical | Physical | Physical |
| | AR coating layer | Not | Not | Not | Not | Not | Not |
| | | formed | formed | formed | formed | formed | formed |
| | Etching amount [μm] | 50 | 50 | 0 | 10 | 0 | 10 |
| | Number density [number/cm²] | 255.0 | 278.0 | 0.0 | 0.2 | 0.0 | 0.3 |
| | of concave portions | | | | | | |
| | Resin layer | Formed | Formed | Formed | Formed | Formed | Formed |
| Back | Glass material | B | B | PET | PET | C | C |
| surface-side | Glass plate | B10H | B11H | — | — | B13 | B13H |
| glass plate | Thickness [mm] | 2.0 | 2.0 | — | — | 2.0 | 2.0 |
| | Strengthening treatment | Physical | Physical | — | — | — | — |
| | Etching amount [μm] | 50 | 50 | — | — | 10 | 10 |
| | Etching surface | Both | Back | — | — | — | — |
| | | surfaces | surface | | | | |
| | Number density [number/cm²] | 233.0 | 267.0 | — | — | 0.4 | 0.2 |
| | of concave portions | | | | | | |
| | Hole | Formed | Formed | — | — | Formed | Formed |
| Module | Light receiving surface-side | A | A | A | A | B | A |
| strength | glass plate: 46J | | | | | | |
| test | Light receiving surface-side | A | A | B | A | — | A |
| | glass plate: 89J | | | | | | |
| | Back surface-side glass plate: 46J | A | A | — | — | B | A |
| | Back surface-side glass plate: 89J | A | A | — | — | — | A |

From the results of Table 2, it has been confirmed that the glass plate having concave portions with a size of 1 to 100 μm and a depth of 0.01 to 10 μm at 0.1 number/cm² or more in at least one surface thereof is excellent in resistance to falling objects.

It has been confirmed from the results of Table 3 that the solar cell module is improved in strength against falling objects by the application of the glass plate having concave portions with a size of 1 to 100 μm and a depth of 0.01 to 10 μm at 0.1 number/cm² or more in at least one surface thereof.

When a solar cell module was produced in the same manner as in Ex. 20 except that a resin layer was not peeled off and was used as an adhesive layer and then was evaluated in the same manner as in Ex. 20, the same level of results as in Ex. 20 was obtained.

### REFERENCE SYMBOLS

10: Glass plate
12, 12a, 12b: Light receiving surface-side glass plate
14, 14a, 14b: Back surface-side glass plate
16, 20: Resin layer
30: Resin layer-attached glass plate
40: Solar cell substrate
40a: Light receiving surface
40b: Back surface
50, 50a, 50b, 50c, 50d, 50e, 50f: Solar cell module
60: Falling ball impact tester
62: Steel ball
64: Windable string
66: Stopper
70: Stage
72: Jig
74: Sample

1-19. (canceled)

20. A method for producing a solar cell module, the solar cell module comprising a glass plate and a solar cell substrate, the method comprising: performing etching and cleaning on at least one surface of the glass plate, and then, forming a resin layer on the one surface without substantially increasing scratches on the one surface,
wherein the glass plate has concave portions with a size of 1 to 100 μm and a depth of 0.01 to 10 μm at 0.1 number/cm2 or more in a solar cell substrate-side surface of the glass plate.

21. The method for producing a solar cell module according to claim 20, wherein the resin layer is formed on the one surface without allowing contact of any object other than the resin layer.

22. The method for producing a solar cell module according to claim 20, wherein the glass plate is of chemically strengthened glass or physically strengthened glass.

23. The method for producing a solar cell module according to claim 20, wherein the etching is performed only on the one surface of the glass plate.

24. The method for producing a solar cell module according to claim 20, comprising: performing etching and cleaning on at least one surface of the glass plate; and placing the solar cell substrate on the one surface.

25. The method for producing a solar cell module according to claim 20,
wherein the solar cell substrate has a light receiving surface and a back surface opposite to the light receiving surface,
wherein the glass plate is a light receiving surface-side glass plate arranged on the light receiving surface side of the solar cell substrate,
wherein the light receiving surface-side glass plate satisfies at least one of the following requirements A1, A2 and A3:
requirement A1: the depth of layer of compressive stress on a solar cell substrate side of the light receiving surface-side glass plate is smaller than the depth of layer of compressive stress on a side of the light receiving surface-side glass plate opposite to the solar cell substrate side;
requirement A2: the compressive stress on the solar cell substrate side of the light receiving surface-side glass plate is lower than the compressive stress on the side of the light receiving surface-side glass plate opposite to the solar cell substrate side; and
requirement A3: the light receiving surface-side glass plate is warped in a convex shape toward the side opposite to the solar cell substrate side.

26. The method for producing a solar cell module according to claim 25,
wherein at least a part of a peripheral edge region of the light receiving surface-side glass plate is reduced in thickness to define a step portion on a surface of the light receiving surface-side glass plate opposite to the solar cell substrate.

27. The method for producing a solar cell module according to claim 20,
wherein the solar cell substrate has a light receiving surface and a back surface opposite to the light receiving surface,
wherein the glass plate comprises a light receiving surface-side glass plate arranged on the light receiving surface side of the solar cell substrate and a back surface-side glass plate arranged on the back surface side of the solar cell substrate, and
wherein the etching and cleaning are performed on at least one of a solar cell substrate-side surface of the light receiving surface-side glass plate and a surface of the back surface-side glass plate opposite to the solar cell substrate.

28. The method for producing a solar cell module according to claim 27, wherein the etching and cleaning are performed on the back surface-side glass plate with a hole formed therein.
